(19) United States
(12) Patent Application Publication
(10) Pub. No.: US 2012/0199887 A1
(43) Pub. Date: Aug. 9, 2012

(54) METHODS OF CONTROLLING TUNGSTEN FILM PROPERTIES

(76) Inventors: Lana Chan, Northborough, MA (US); Feng Chen, Milpitas, CA (US); Roey Shaviv, Palo Alto, CA (US)

(21) Appl. No.: 13/020,748

(22) Filed: Feb. 3, 2011

(51) Int. Cl. H01L 29/772; C23C 16/46; C23C 16/44; H01L 21/28; C23C 16/06

(52) U.S. Cl. 257/288; 438/680; 118/725; 118/697; 257/E21.158; 257/E29.242

(57) ABSTRACT

Methods, apparatus, and systems for depositing tungsten having tailored stress levels are provided. According to various embodiments, the methods involve depositing high stress or low stress tungsten films. In certain embodiments depositing high stress tungsten involves a multi-stage chemical vapor deposition (CVD) process including a low temperature deposition followed by a high temperature deposition. In certain embodiments depositing low stress tungsten involves a CVD process using a relatively low tungsten precursor flow. Also provided are new classes of high and low stress tungsten films, which may also have low resistivity and/or high reflectivity. Also provided are integration methods involving depositing high or low stress tungsten, for example as contacts and/or metal gates, and semiconductor devices incorporating the tungsten films.

### BACKGROUND

The deposition of tungsten films using chemical vapor deposition (CVD) techniques is an integral part of many semiconductor fabrication processes. Tungsten films may be used as low resistivity electrical connections in the form of horizontal interconnects, vias between adjacent metal layers, and contacts between a first metal layer and the devices on the silicon substrate. In a conventional tungsten deposition process, the wafer is heated to the process temperature in a vacuum chamber, and then a very thin portion of tungsten film, which serves as a seed or nucleation layer, is deposited. Thereafter, the remainder of the tungsten film (the bulk layer) is deposited on the nucleation layer. Conventionally, the tungsten bulk layer is formed by the reduction of tungsten hexafluoride (WF₆) with hydrogen (H₂) on the growing tungsten layer.

### SUMMARY

Methods, apparatus, and systems for depositing tungsten having tailored stress levels are provided. According to various embodiments, the methods involve depositing high stress or low stress tungsten films. In certain embodiments depositing high stress tungsten involves a multi-stage chemical vapor deposition (CVD) process including a low temperature deposition followed by a high temperature deposition. In certain embodiments depositing low stress tungsten involves a CVD process using a relatively low tungsten precursor flow. Also provided are new classes of high and low stress tungsten films, which may also have low resistivity and/or high reflectivity. Also provided are integration methods involving depositing high or low stress tungsten, for example as contacts and/or metal gates, and semiconductor devices incorporating the tungsten films.

In certain embodiments, a method includes providing a substrate to a chamber. The substrate includes a field region and a feature recessed from the field region, and the feature includes sidewalls and a bottom. A tungsten nucleation layer is deposited on the sidewalls and the bottom of the feature. The feature is filled with tungsten via a first chemical vapor deposition process using a tungsten precursor. During the first chemical vapor deposition process, the substrate temperature is maintained at about 330 to 450° C. and the partial pressure of the tungsten precursor in the chamber is less than about 1 Torr.

In certain embodiments, a method includes providing a substrate to a chamber. The substrate includes a field region and a feature recessed from the field region, and the feature includes sidewalls and a bottom. A tungsten nucleation layer is deposited on the sidewalls and the bottom of the feature. The tungsten nucleation layer is exposed to a plurality of reducing agent pulses. The feature is partially filled with tungsten via a first chemical vapor deposition process. During the first chemical vapor deposition process, the substrate temperature is maintained at about 100 to 330° C. The feature is filled with tungsten via a second chemical vapor deposition process. During the second chemical vapor deposition process, the substrate temperature is maintained at about 330 to 450° C. The second chemical vapor deposition process is performed at a temperature at least about 100° C. higher than the first chemical vapor deposition process.

In certain embodiments, a PMOS transistor structure includes a substrate, a gate dielectric disposed on the substrate, and a metal gate separated from the substrate by the gate dielectric. The substrate includes a source region and a drain region in the substrate on either side of the metal gate and a channel region underlying the gate dielectric. The channel region is strained by forces in the metal gate to decrease a lattice constant of the channel region.

In certain embodiments, a NMOS transistor structure includes a substrate, a gate dielectric disposed on the substrate, a metal gate separated from the substrate by the gate dielectric, and a dielectric film. The substrate includes a source region and a drain region in the substrate on either side of the metal gate and a channel region underlying the gate dielectric. The channel region is strained by the dielectric film and unstrained by the metal gate to increase a lattice constant of the channel region.

In certain embodiments, a deposition apparatus includes a deposition chamber. The deposition chamber is configured to deposit a tungsten nucleation layer on sidewalls and a bottom of the feature, the feature being recessed from a field region of a substrate including the field region. The deposition chamber is further configured to fill the feature with tungsten via a first chemical vapor deposition process using a tungsten precursor. During the first chemical vapor deposition process, the substrate temperature is maintained at about 330 to 450° C. and the partial pressure of the tungsten precursor in the deposition chamber is less than about 1 Torr.

In certain embodiments, an apparatus for depositing tungsten includes a process chamber and a controller. The controller includes program instructions for conducting a process including providing a substrate to the process chamber, the substrate including a field region and a feature recessed from the field region, the feature including sidewalls and a bottom; depositing a tungsten nucleation layer on the sidewalls and the bottom of the feature; and filling the feature with tungsten via a first chemical vapor deposition process using a tungsten precursor. During the first chemical vapor deposition process, the substrate temperature is maintained at about 330 to 450° C. and the partial pressure of the tungsten precursor in the process chamber is less than about 1 Torr.

In certain embodiments, a non-transitory computer machine-readable medium includes program instructions for control of a deposition apparatus. The instructions include providing a substrate to the deposition apparatus, the substrate including a field region and a feature recessed from the field region, the feature including sidewalls and a bottom; depositing a tungsten nucleation layer on the sidewalls and the bottom of the feature; and filling the feature with tungsten via a first chemical vapor deposition process using a tungsten precursor. During the first chemical vapor deposition process, the substrate temperature is maintained at about 330 to 450° C. and the partial pressure of the tungsten precursor in the deposition apparatus is less than about 1 Torr.

These and other aspects of the invention are described further below with reference to the figures.

### BRIEF DESCRIPTION OF THE DRAWINGS

The accompanying drawings, which are incorporated in and form part of the specification, illustrate embodiments of the invention, and together with the detailed description, serve to explain embodiments of the invention:

FIG. 1 is a schematic diagram of a PMOS device according to certain embodiments.

FIG. 2 is a schematic diagram of a NMOS device according to certain embodiments.

FIG. 3 is a schematic diagram of a PMOS device according to certain embodiments.

FIG. 4 is a schematic diagram of a NMOS device according to certain embodiments.

FIG. 5 is a schematic diagram of a semiconductor device according to certain embodiments.

FIG. 6 depicts a process flow diagram illustrating operations in a method of fabricating a semiconductor device according to certain embodiments.

FIGS. 7-9 depict process flow diagrams illustrating operations in methods of depositing low stress tungsten according to certain embodiments.

FIG. 10 depicts a process flow diagram illustrating operations in a method of depositing a tungsten nucleation layer according to certain embodiments.

FIGS. 11A and 11B illustrate examples of gas pulse sequences in low resistivity treatments according to certain embodiments.

FIG. 12 is a plot illustrating film stress of a 250 nm thick tungsten film as a function of tungsten hexafluoride partial pressure during a tungsten CVD process.

FIG. 13 is a plot illustrating film stress of a 1500 Angstrom thick tungsten film as a function of temperature during a tungsten CVD process.

FIG. 14 is a plot illustrating film stress of a 100 nm thick tungsten film as a function of film resistivity.

FIG. 15 is a schematic diagram illustrating feature cross-sections at different stages of a tungsten deposition process.

FIG. 16 depicts a process flow diagram illustrating operations in a method of depositing high stress tungsten according to certain embodiments.

FIG. 17 is a bar graph illustrating film stress of a 100 nm thick tungsten film for various tungsten deposition processes.

FIG. 18 is a schematic diagram of a processing system suitable for conducting tungsten deposition processes in accordance with various embodiments.

FIG. 19 is a schematic diagram of a deposition station suitable for conducting tungsten deposition processes in accordance with various embodiments.

### DETAILED DESCRIPTION

### Introduction

In the following detailed description of the present invention, numerous specific embodiments are set forth in order to provide a thorough understanding of the invention. However, as will be apparent to those of ordinary skill in the art, the present invention may be practiced without these specific details or by using alternate elements or processes. In other instances well-known processes, procedures, and components have not been described in detail so as not to unnecessarily obscure aspects of the present invention.

In this application, the terms “semiconductor wafer,” “wafer,” and “partially fabricated integrated circuit” are used interchangeably. One of ordinary skill in the art would understand that the term “partially fabricated integrated circuit” can refer to a silicon wafer during any of many stages of integrated circuit fabrication thereon. The following detailed description assumes the invention is implemented on a wafer. However, the invention is not so limited. The work piece may be of various shapes, sizes, and materials. In addition to semiconductor wafers, other work pieces that may take advantage of this invention include various articles such as printed circuit boards and the like.

The straining of silicon in order to increase the mobility of charge carriers is used in technology nodes of 90 nm and smaller. This may be done by introducing high stress nitride liners as the first step in a pre-metal dielectric sequence. For example, a nitride liner film is used to strain silicon in a metal-oxide-semiconductor field-effect transistor (MOSFET); a tensile film is used to strain a n-type metal-oxide-semiconductor field-effect transistor (NMOS) and a compressive film is used to strain a p-type metal-oxide-semiconductor field-effect transistor (PMOS). Straining the channel region of a NMOS device to increase the lattice constant of the silicon in this region increases the mobility of electrons in the channel region, improving device performance. Straining the channel region of a PMOS device to decrease the lattice constant of the silicon in this region increases the mobility of holes in the channel region, improving device performance. Increasing the mobility of charge carriers, i.e., electrons or holes, in field-effect transistor devices allows the devices to operate faster and with less power loss. In “gate-last” integration MOSFET devices, however, high stress films are located a distance away from the silicon, and as a result their effect on device performance is compromised.

Semiconductor device performance may also be improved by varying the stress induced by metal films formed in the gate and contacts of a semiconductor device. Traditionally, aluminum is used as the gate metal in gate-last integration of semiconductor devices, and does not significantly stress the underling channel region. A low stress tungsten film as a metal in a NMOS device metal gate or a high stress tungsten film as a metal in a PMOS device metal gate, however, may be used to enhance device performance, as described further below. Further, the stress of a tungsten metal film inside the contact of a semiconductor device plays no significant role in traditional semiconductor manufacturing. A high stress tungsten film in NMOS device contacts or a low stress tungsten film in PMOS device contacts, however, may be used to enhance device performance, as also described further below.

A typical tungsten film used to fill a high-aspect ratio feature may require a high stress film to provide good conformity, plug fill, and adhesion to barrier layers. The stress level in such a tungsten film ranges from about 1.2×10¹⁰ dyne/cm² (1.2 gigapascals) to about 1.4×10¹⁰ dyne/cm² (1.4 gigapascals) for a film thicker than about 2,000 Å. A typical tungsten film used as an interconnect may require a low stress film at the expense of step coverage. The stress level in such a low stress film may be less than about 1×10¹⁰ dyne/cm² (1 gigapascal) for a film thicker than about 2,000 Å.

Tungsten deposition methods disclosed herein may produce high stress films and low stress films to achieve strain enhancement in PMOS devices, NMOS devices, and other semiconductor device applications. Applications of high stress tungsten films may require about a 50% increase in the typical stress levels needed for plug fill, for example.

### Devices

To improve PMOS device performance, the mobility of holes in the channel region under the gate region of the device should be increased. This may be achieved by straining the silicon under the gate to reduce the lattice constant. A SiGe alloy in the source and drain areas, with a lattice constant greater than that of the silicon under the gate, is often used to strain the silicon under the gate to reduce the lattice constant.

Similarly, a stressed metal filling the gate would exert a force on the silicon in the channel, reducing the lattice constant. Thus, a high stress metal gate, applying a compressive force to the silicon, would benefit PMOS device performance.

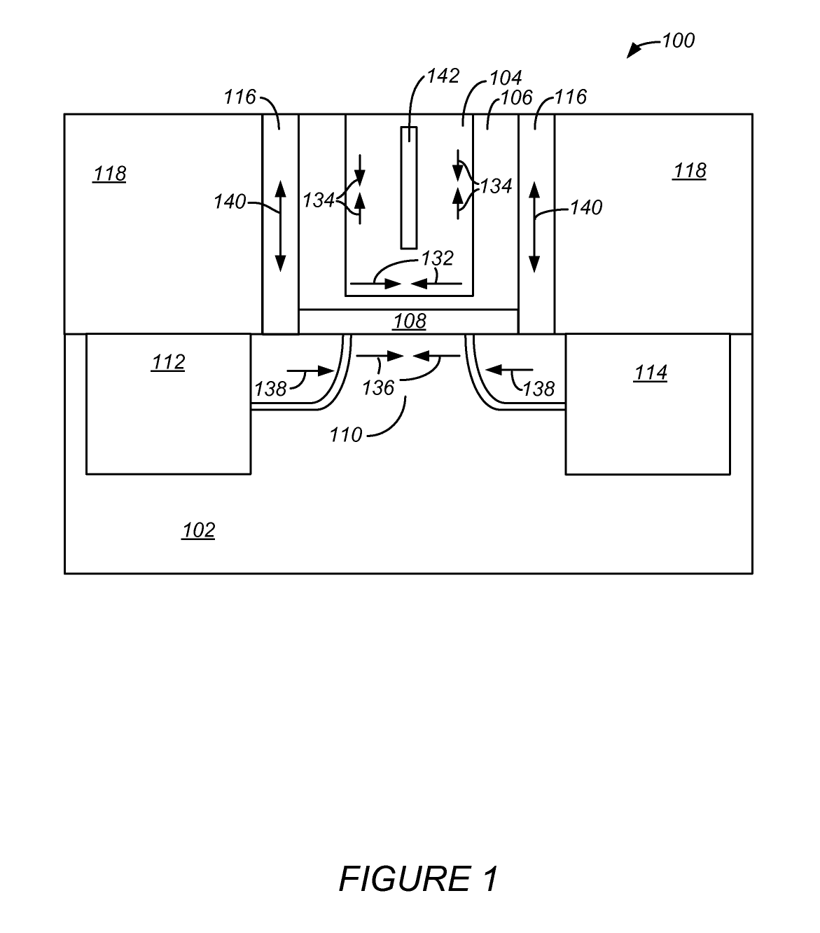

FIG. 1 is a schematic diagram of a PMOS device according to certain embodiments. The PMOS device 100 shown in FIG. 1 includes a substrate 102, a conductive gate 104 separated from the substrate 102 by a metal 106, and a gate dielectric 108. The channel region 110 in the substrate 102 separates p-type source 112 and drain 114 regions. Dielectric spacers 116 are associated with the gate region. A dielectric film 118 completes the depicted PMOS device. Note that contacts for the source 112 and drain 114 regions are not shown in FIG. 1. The substrate 102 is silicon in some embodiments. The source 112 and the drain 114 regions include a SiGe alloy to reduce the lattice constant of the substrate in the channel region 110 in some embodiments. Gallium arsenide and other semiconductor materials, for example, may also be used as the substrate 102, the source 112, and the drain 114.

In some embodiments the conductive gate 104 of the PMOS device 100 includes high stress tungsten. The vectors shown in FIG. 1 illustrate the effect of high stress tungsten in the PMOS device 100. The high stress tungsten may exhibit different stresses. Some stresses in the high stress tungsten may be in a plane parallel to the plane of the substrate 102 (parallel stresses) and some stresses in the high stress tungsten may be in a plane normal to the plane of the substrate 102 (normal stresses). The parallel stresses of the high stress tungsten are indicated by vectors 132. The normal stresses of the high stress tungsten are indicated by vectors 134.

The substrate 102 is strained by the parallel stresses of high stress tungsten in the conductive gate 104. The parallel stresses 132 of the tungsten exert stresses 136 on the channel region 110. The parallel stresses 132 are compressive and the stresses 136 are compressive. The stresses 136 reduce the lattice constant of the channel region 110 of the substrate 102, which increases the mobility of holes in the channel region. The stresses 136 are added to the stresses 138 exerted on the channel region by the source 112 and drain 114 regions when the source and drain regions include SiGe, for example.

In some embodiments the normal stresses of the high stress tungsten play a minimal role in the PMOS device 100. The normal stresses 134 of the tungsten are balanced by the stresses 140 of the compressive dielectric spacers and may have no effect on the substrate 102 lattice constant. If present, the small seam 142 at the center of the high stress tungsten of the conductive gate 104 may also aid in neutralizing the normal stresses. As a result, the parallel stresses 132 of the tungsten at the bottom of the conductive gate 104 have a significant effect on the lattice constant of the substrate 102, and not the normal stresses 134.

To improve NMOS device performance, the mobility of electrons in the channel under the gate should be increased. This is achieved with a tensile dielectric film encapsulating the NMOS device in some embodiments. The dielectric film strains the source and drain areas, which in turn increases the lattice constant in the channel. A low stress or stress free metal gate would therefore benefit NMOS performance. Titanium nitride (TiN) or tantalum nitride (TaN) may be used in the metal gate region to aid in increasing the lattice constant in the channel. Similarly, a low stress or stress neutral tungsten metal gate would exert little stress on the silicon in the channel and avoid opposing stresses imposed by other films or materials.

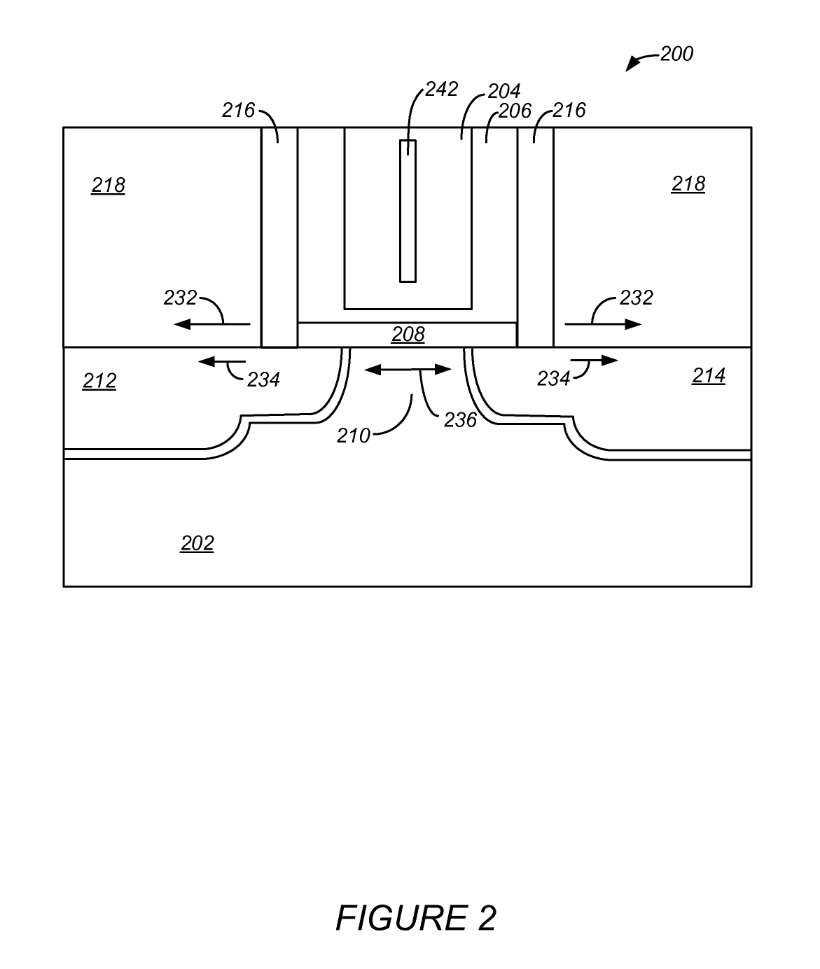

FIG. 2 is a schematic diagram of a NMOS device according to certain embodiments. The NMOS device 200 shown in FIG. 2 includes a substrate 202, a conductive gate 204 separated from the substrate 202 by a metal 206 and a gate dielectric 208. The channel region 210 in the substrate 202 separates n-type source 212 and drain 214 regions. Dielectric spacers 216 are associated with the gate region. A dielectric film 218 completes the depicted NMOS device. Note that contacts for the source 212 and drain 214 regions are not shown in FIG. 2.

The dielectric film 218 is a tensile dielectric film in some embodiments. The vectors shown in FIG. 2 illustrate the effect of a tensile dielectric film in the NMOS device 200. The parallel stresses 232 of the tensile dielectric film exert stresses 234 on the source 212 and drain 214 regions. The stresses 234 in turn create a stress 236 in the channel region 210 of the substrate 202 that strains the channel region 210, which increases the mobility of electrons in the channel region.

The conductive gate 204 of the NMOS device 200 includes a low stress or stress neutral tungsten that aids in increasing the silicon lattice constant in the channel region 210. Increasing the lattice constant in the channel region 210 enhances the electron mobility in this region. In certain embodiments, a seam 242 is present in the gate 204.

PMOS and NMOS device performance by stress control may also be achieved using a low stress or a high stress metal in the contacts to source and drain, respectively. Tungsten metal is the traditional and most wildly used contact metallization metal. Tailoring the stress of the tungsten inside the source and drain contacts offers an effective, cost neutral, and reliable method for enhancing device performance. This approach is compatible with both the traditional cylindrical contact metallization and with the emerging technology using cylindroid-shaped contact metallization.

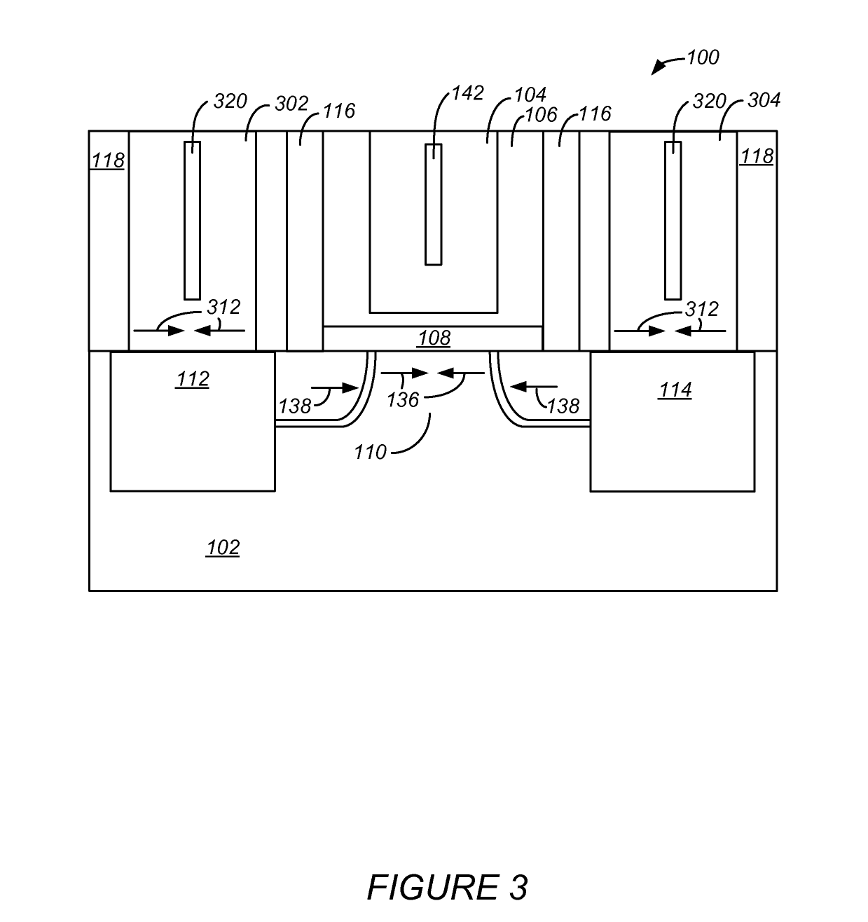

FIG. 3 is a schematic diagram of a PMOS device according to certain embodiments. The PMOS device 100 shown in FIG. 3 is that same PMOS device 100 shown in FIG. 1, with the addition of contact 302 for the source region 112 and contact 304 for the drain region 114.

In certain embodiments the contacts 302 and 304 include a low stress or stress neutral tungsten. The vectors shown in FIG. 3 illustrate the effect of low stress or stress neutral tungsten in the contacts 302 and 304 of the PMOS device 100. The low stress or stress neutral tungsten exhibits a small parallel stress indicated by vectors 312 and does not add any additional stress on the source 112 and drain 114 regions or the channel region 110. In contrast, a high stress tungsten contact metallization would serve to increase the lattice constant of the channel region 110 and have a detrimental effect on the PMOS device performance. In certain embodiments, a seam 320 is present in contacts 302 and 304.

Certain embodiments of a PMOS device include high stress tungsten in the gate region. Certain embodiments of a PMOS device include low stress tungsten for contacts to the source and drain regions. Certain embodiments of a PMOS device include high stress tungsten in the gate region and low stress tungsten for contacts to the source and drain regions.

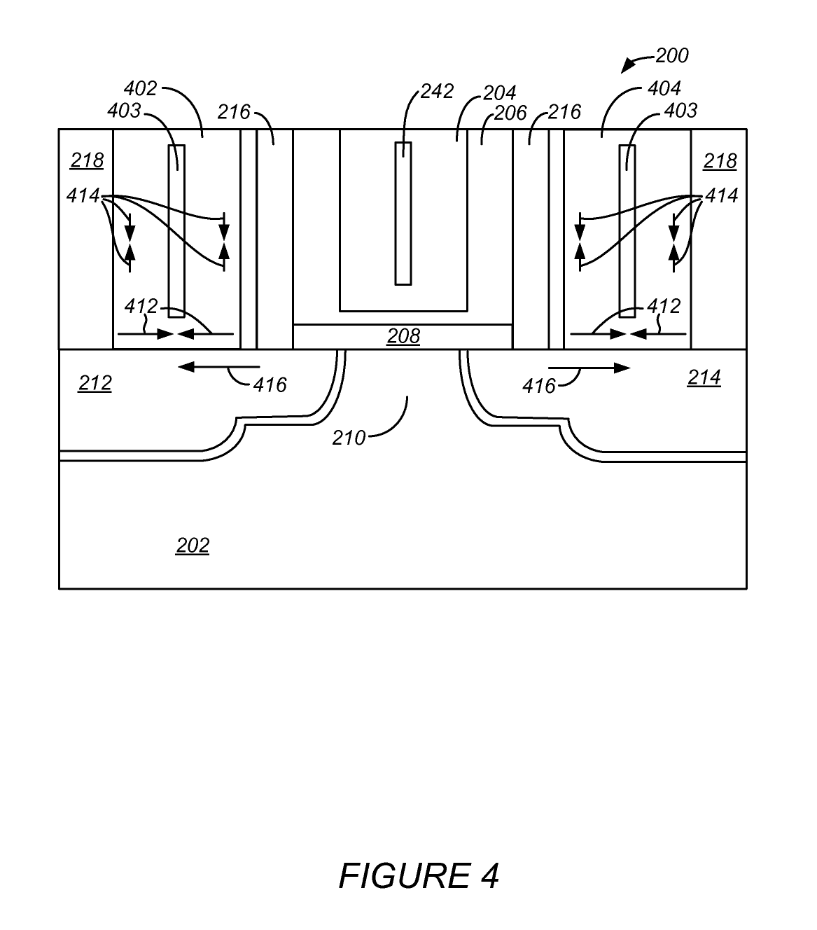

FIG. 4 is a schematic diagram of a NMOS device according to certain embodiments. The NMOS device 200 shown in FIG. 4 is the same NMOS device 200 shown in FIG. 1, with the addition of contact 402 for the source region 212 and contact 404 for the drain region 214.

In certain embodiment, the contacts 402 and 404 include high stress tungsten. The vectors shown in FIG. 4 illustrate the effect of high stress tungsten in the contacts 402 and 404 of the NMOS device 200. The high stress tungsten may exhibit different stresses. Some stresses in the high stress tungsten may be in a plane parallel to the plane of the substrate 202 (parallel stresses) and some stresses in the high stress tungsten may be in a plane normal to the plane of the substrate 202 (normal stresses). The parallel stresses of the high stress tungsten are indicated by vectors 412. The normal stresses of the high stress tungsten are indicated by vectors 414. The small seams 403 at the center of the high stress tungsten of the contacts 402 and 404 may aid in neutralizing the normal stresses 414.

The source 212 and drain 214 regions of substrate 202 are strained by the parallel stresses of high stress tungsten in the contacts 402 and 404. The parallel stresses 412 of the tungsten exert stresses 416 in the source 212 and drain 214 regions. The stresses 416 in the source 212 and drain 214 regions increase the lattice constant of the silicon in the channel region 210, which increases the electron mobility in the channel region.

Certain embodiments of a NMOS device include low stress tungsten in the gate region. Certain embodiments of a NMOS device include high stress tungsten for contacts to the source and drain regions. Certain embodiments of a NMOS device include low stress tungsten in the gate region and high stress tungsten for contacts to the source and drain regions.

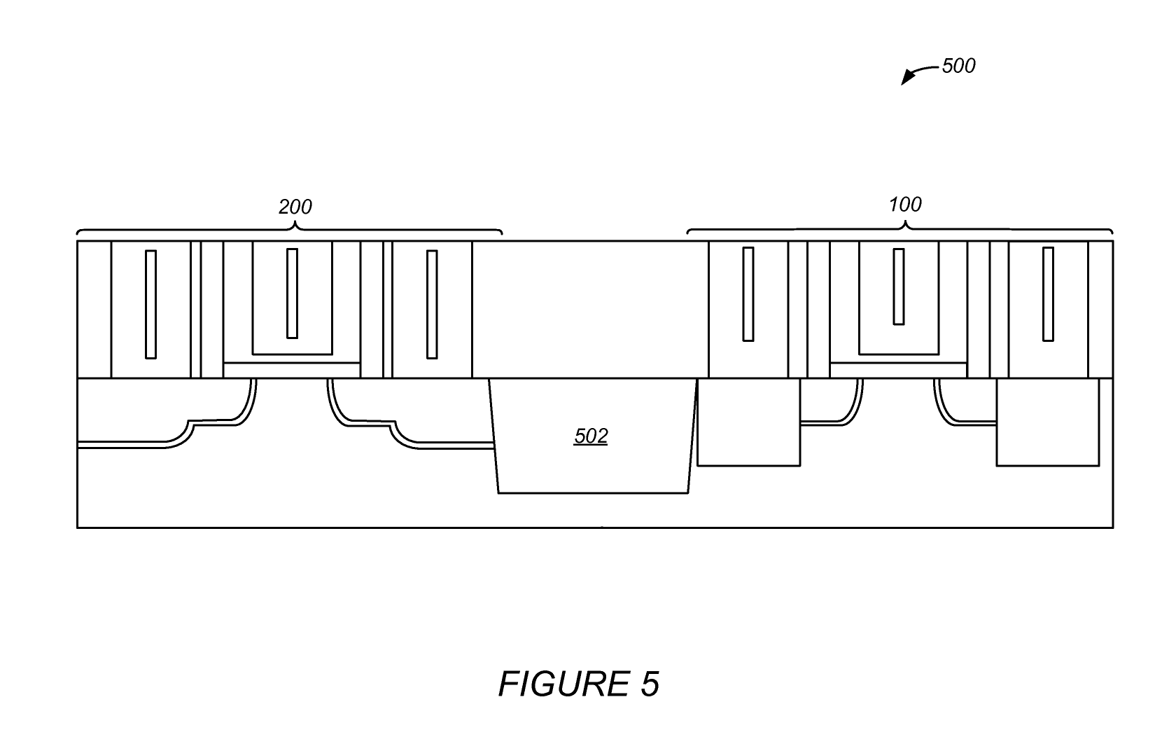

FIG. 5 is a schematic diagram of a semiconductor device according to certain embodiments. The semiconductor device 500 shown in FIG. 5 includes a PMOS device 100 and a NMOS device 200. The PMOS device 100 and the NMOS device 200 are isolated from one another using a shallow trench isolation feature 502. Embodiments of the PMOS device 100 may include high stress tungsten in the gate region and/or low stress tungsten for contacts to the source and drain regions. Embodiments of the NMOS device 200 may include low stress tungsten in the gate region and/or high stress tungsten for contacts to the source and drain regions.

Methods for forming high stress, low stress, and stress neutral tungsten films are described below.

### Methods

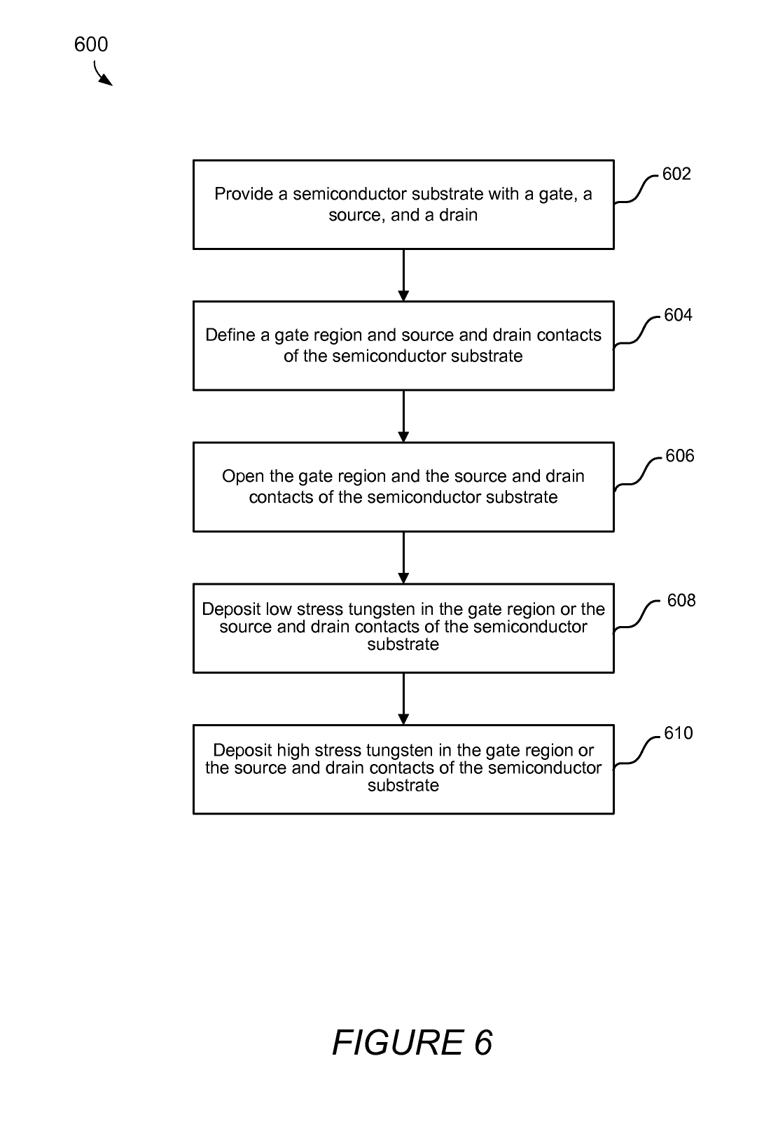

FIG. 6 depicts a process flow diagram illustrating operations in a method 600 of fabricating a semiconductor device according to certain embodiments. For example, the semiconductor device may include a PMOS device and/or a NMOS device, as described above. Embodiments of the method 600 may be used in “gate-first” and “gate-last” integration schemes.

In operation 602, a semiconductor substrate having a gate, a source, and a drain is provided. The gate, the source, and the drain may be a gate, a source, and a drain for a PMOS or NMOS device, as described above. Further, the semiconductor substrate may include more than one gate, source, and drain for multiple PMOS and/or NMOS devices.

In operation 604, a gate region and the source and drain contacts are defined. The source and drain contacts contact the source and drain of the semiconductor substrate. The gate region and the source and drain contacts may be defined using photolithography techniques and/or sacrificial films, as known to one having ordinary skill in the art.

In operation 606, the gate region and the source and drain contacts are opened. For example, the gate region and the source and drain contracts may be opened with etching techniques, including wet and dry chemical etching.

In operation 608, a low stress tungsten film is deposited in selected gate regions and/or source and drain contacts, as described herein. Areas where the low stress tungsten film is deposited may be defined using photolithography techniques and/or sacrificial films, for example.

In operation 610, a high stress tungsten film is deposited in selected gate regions and/or source and drain contacts, as described herein. Areas where the high stress tungsten film is deposited may be defined using photolithography techniques and/or sacrificial films, for example.

One having skill in the art will understand that particular sequence of operations may vary according to the implementation and that one or more operations may be omitted or additional operations may be performed. For example, in certain embodiments, neutral stress tungsten or another metal may be deposited in addition to or instead of the low or high stress tungsten.

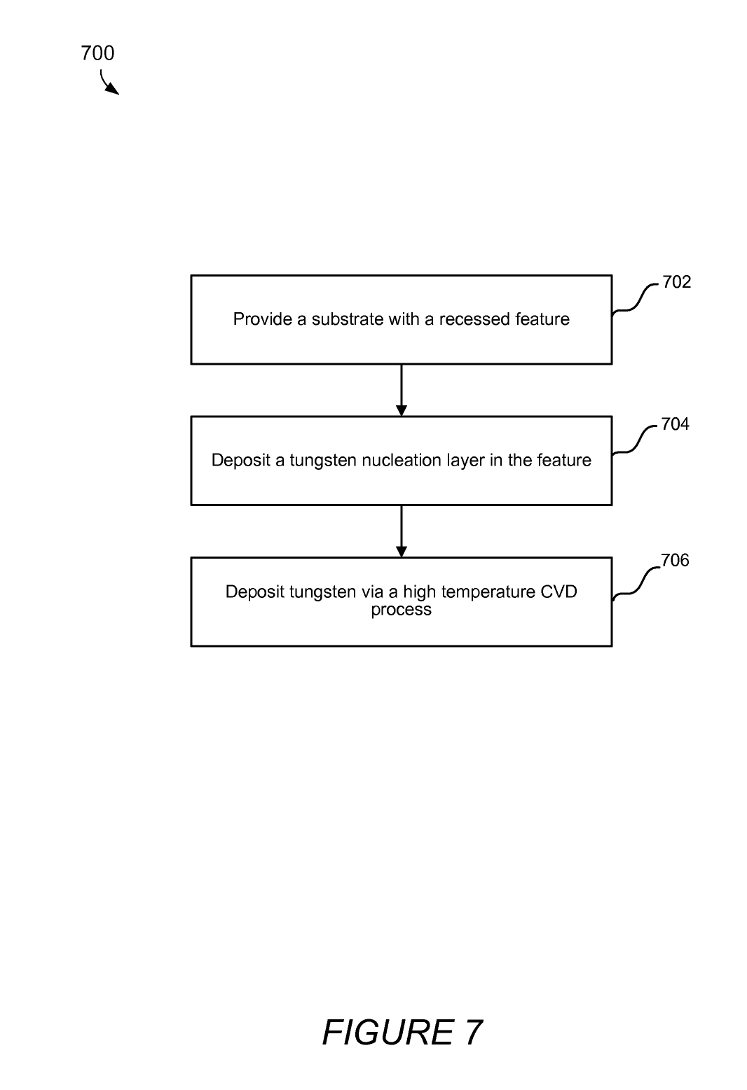

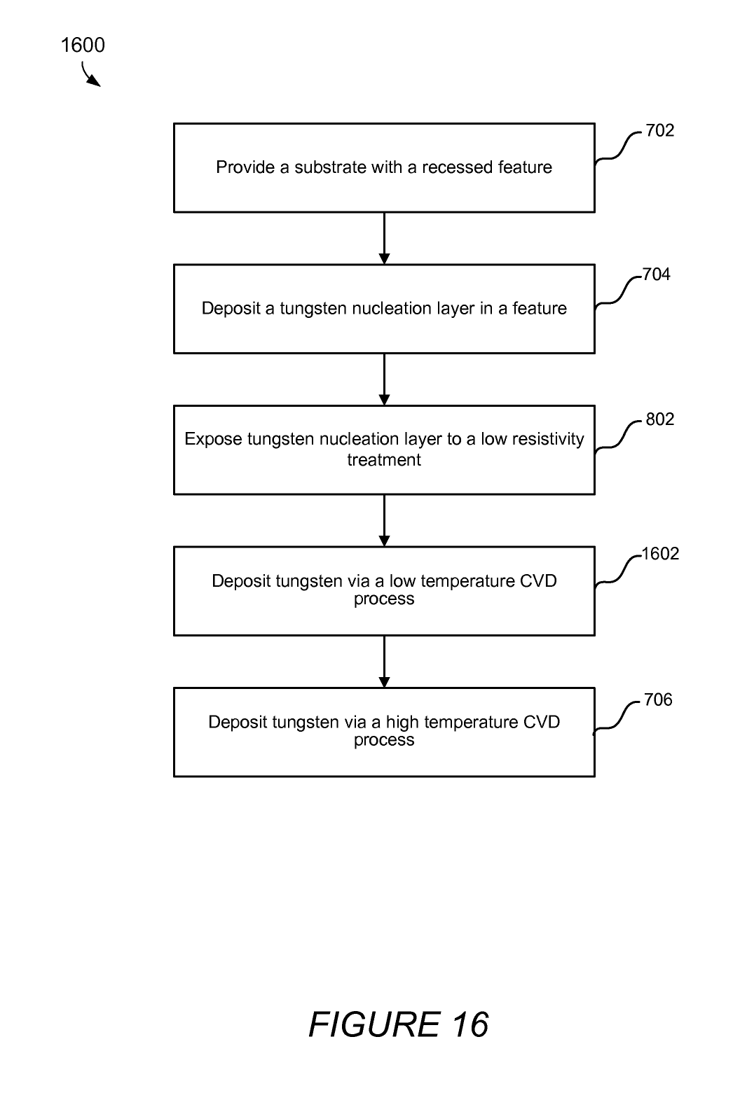

FIGS. 7-9 depict process flow diagrams illustrating operations in methods of depositing low stress tungsten film according to certain embodiments. FIG. 16 depicts a process flow diagram illustrating operations in a method of depositing high stress tungsten film according to certain embodiments. Both the low stress tungsten film deposition processes and the high stress tungsten film deposition processes may be used to deposit tungsten in features on a substrate.

FIG. 7 depicts a process flow diagram illustrating operations in a method 700 of depositing low stress tungsten film according to certain embodiments. In operation 702, a substrate having a recessed feature is provided. In certain embodiments the feature is a high-aspect ratio feature. According to various embodiments the substrate feature has an aspect ratio of at least 5:1, at least 10:1, at least 15:1, at least 20:1, at least 25:1, or at least 30:1. According to various embodiments the feature size is characterized by the feature opening size in addition to or instead of the aspect ratio. For example, the feature opening size may be about 10 to 100 nanometers (nm) wide or about 10 to 50 nm wide. In certain embodiments the methods may be used with features having narrow openings, regardless of the aspect ratio. In some embodiments a feature includes sloped sidewalls such that the feature opening size is smaller than the width of the feature at the bottom of the feature. In some embodiments a feature includes cavities and/or further features within the feature.

In certain embodiments the feature is formed within a dielectric layer on a substrate, with the bottom of the feature providing contact to an underlying metal layer. For example, the feature may be a contact for the source or drain region of a PMOS or NMOS device. In certain embodiments the feature is formed within a metal layer on a substrate. For example, the feature may be a metal in the gate region of a PMOS or NMOS device that is used to tune the work function difference between the gate and the channel region. In certain embodiments the feature includes a liner/barrier layer on its sidewalls and/or bottom. Examples of liner layers include Ti/TiN, TiN, WN, TiC, and WC. In addition to or instead of diffusion barrier layers, the feature may include layers such as an adhesion layer, a nucleation layer, a combination of thereof, or any other applicable material lining the sidewalls and bottom of the feature.

In operation 704, a tungsten nucleation layer is deposited in the feature. In some embodiments the tungsten nucleation layer conformally coats the sidewalls and bottom of the feature. In general, a nucleation layer is a thin conformal layer which serves to facilitate the subsequent formation of a bulk material thereon. Conformation of a nucleation layer to the underlying feature is important in supporting high quality film deposition. Various processes may be used to form the nucleation layer, including but not limited to, chemical vapor deposition (CVD) processes, atomic layer deposition (ALD) processes, and pulsed nucleation layer (PNL) deposition processes.

In a PNL process, pulses of reactants are sequentially injected and purged from the reaction chamber, typically by a pulse of a purge gas between reactants. A first reactant is typically adsorbed onto the substrate, available to react with the next reactant. The process is repeated in a cyclical fashion until the desired nucleation layer thickness is achieved. PNL is similar to ALD techniques reported in the literature. PNL is generally distinguished from ALD by its higher operating pressure range (greater than 1 Torr) and its higher growth rate per cycle (greater than 1 monolayer of film growth per cycle). In the context of the description provided herein, PNL broadly embodies any cyclical process of sequentially adding reactants for reaction on a semiconductor substrate. Thus, the concept embodies techniques conventionally referred to as ALD. In the context of description provided herein, CVD embodies processes in which reactants are together introduced to a reactor for a vapor-phase reaction. PNL and ALD processes are distinct from CVD processes and vice-versa.

Forming a nucleation layer using one or more PNL cycles is discussed in U.S. Pat. Nos. 6,844,258; 7,005,372; 7,141,494; 7,262,125; 7,589,017; and 7,772,114; US Patent Publication Nos. 2008/0254623 and 2010/0159694, all of which are incorporated herein by reference in their entireties. These PNL nucleation layer processes involve exposing a substrate to various sequences of reducing agents and tungsten precursors to grow a nucleation layer of the desired thickness. A combined PNL-CVD method of depositing a nucleation layer is described in U.S. Pat. No. 7,655,567, also incorporated herein by reference in its entirety.

In certain embodiments the nucleation layer is deposited to form a nucleation layer thick enough to support high quality deposition. In certain embodiments the requisite thickness depends in part on the nucleation layer deposition method. As described further below, in certain embodiments a PNL method providing near 100% step coverage nucleation film at thicknesses as low as about 10 Å may be used in certain embodiments. According to various embodiments tungsten nucleation layers of about 30 to 50 Å (3 to 5 nm) may be formed, and in certain embodiments, tungsten nucleation layers of about 10 to 15 Å (1 to 1.5 nm) may be formed.

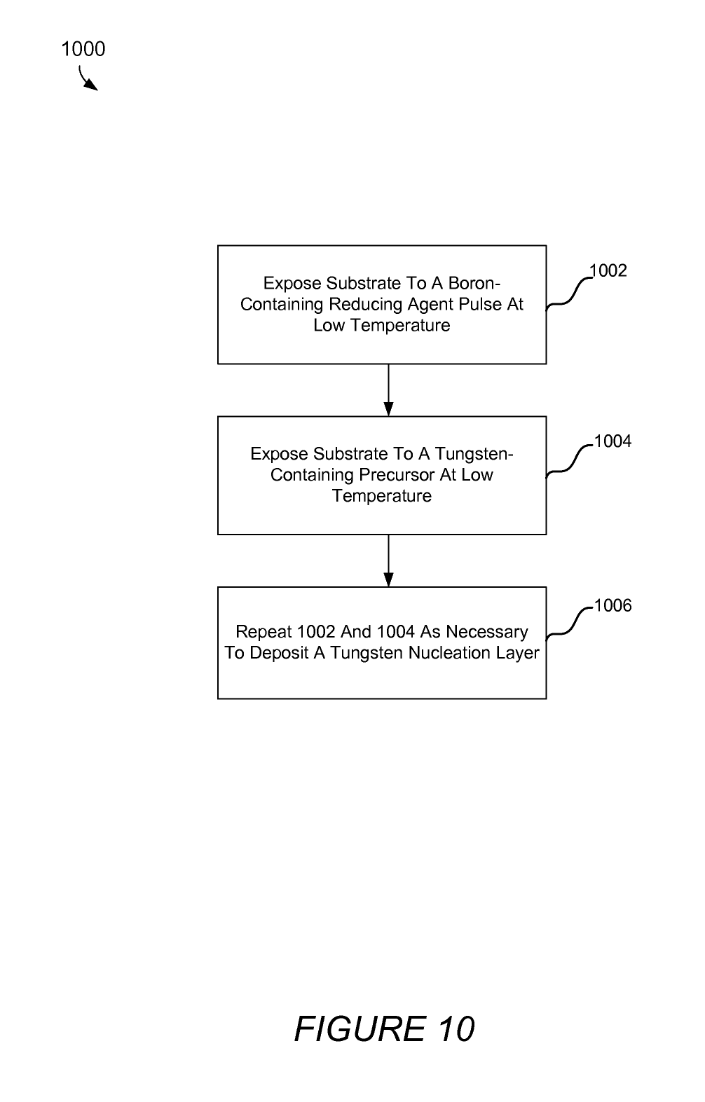

FIG. 10 depicts a process flow diagram illustrating operations in a method 1000 of depositing a tungsten nucleation layer according to certain embodiments. In operation 1002, the substrate is exposed to a boron-containing reducing agent to form a boron-containing layer on the substrate surface. The boron-containing layer is often a layer of elemental boron, though in some embodiments, it may contain other chemical species or impurities from the boron-containing species itself or from residual gases in the reaction chamber. Any suitable boron-containing species may be used, including borane (BH₃), diborane (B₂H₆), triborane, etc. Examples of other boron-containing species include boron halides (e.g., BF₃, BCl₃) with hydrogen.

In some embodiments the substrate temperature is low. For example, the substrate temperature may be below about 350° C., about 250 to 350° C., or about 250 to 325° C. In certain embodiments the temperature is about 300° C. In certain embodiments diborane is provided from a diluted source (e.g., 5% diborane and 95% nitrogen). Diborane may be delivered to a reaction chamber using other or additional carrier gases such as nitrogen and/or argon. In some embodiments no hydrogen is used for depositing a tungsten nucleation layer.

Once the boron-containing layer is deposited to a sufficient thickness, the flow of boron-containing species to the reaction chamber is stopped and the reaction chamber is purged with a carrier gas such as argon, hydrogen, nitrogen, or helium. In certain embodiments only argon is used at the carrier gas. The gas purge clears the regions near the substrate surface of residual gas reactants that could react with fresh gas reactants for the next reaction operation.

Returning to FIG. 10, in operation 1004 the substrate is exposed to a tungsten-containing precursor to form a portion of the tungsten nucleation layer. Any suitable tungsten-containing precursor may be used. In certain embodiments the tungsten-containing precursor is one of WF₆, WCl₆, and W(CO)₆. The tungsten-containing precursor is typically provided in a diluting gas, such as argon, nitrogen, or a combination thereof. As with the boron-containing precursor pulse, the tungsten-containing precursor is delivered in a non-hydrogen environment in some embodiments. In some embodiments the substrate temperature is low. For example, the substrate temperature may be below about 350° C., about 250 to 350° C., or about 250 to 325° C. In certain embodiments the temperature is about 300° C. In many cases, the substrate temperature is the same as during the exposure to the boron-containing species. Tungsten-containing precursor dosage and substrate exposure time will vary depending upon a number of factors. In general, the substrate is exposed until the adsorbed boron species is sufficiently consumed by reaction with the tungsten-containing precursor to produce a portion of the tungsten nucleation layer. Thereafter, the flow of tungsten-containing precursor to the reaction chamber is stopped and the reaction chamber is purged. The resulting portion of tungsten nucleation layer deposited in one boron-containing reducing agent/tungsten-containing precursor PNL cycle may be about 5 Å.

In operation 1006, the low temperature boron-containing reducing agent pulse and tungsten precursor pulse operations are repeated to build up the tungsten nucleation layer to the desired thickness. About 2 to 5 or about 2 to 7 PNL cycles may be required to deposit the very thin nucleation layer in certain embodiments, although in certain embodiments a single cycle may be sufficient. Depending on the substrate, the first one or two cycles may not result in an increase in the thickness of the nucleation layer due to nucleation delay. As described previously, the tungsten nucleation layer is sufficiently thick so as to support a high quality bulk tungsten deposition, in some embodiments. Embodiments of the process described above are able to deposit a tungsten nucleation layer that can support high quality bulk deposition as low as about 10 Angstroms thick in the high-aspect ratio and/or narrow width feature. The thickness of the deposited nucleation layer is typically about 10 to 50 Angstroms, or for example, about 10 to 30 Angstroms.

Temperature is one of the process conditions that affects the amount of tungsten deposited. Other process conditions include pressure, flow rate, and exposure time. Maintaining temperatures at or below about 350° C. results in less material deposited during a cycle. This in turn provides a tungsten nucleation layer with a lower resistivity. In some embodiments temperatures may be about 300° C. or 200° C.

It should be noted that the process depicted in FIG. 10 is one example of appropriate nucleation layer deposition process; other nucleation layer deposition processes may be used. For example, in the process depicted in FIG. 10, the boron-containing reducing agent is the sole reducing agent. In other PNL nucleation layer deposition processes, other reducing agents such as silanes may be pulsed in addition to or instead of boranes or other boron-containing reducing agents. Moreover, as indicated above, deposition methods other than PNL may be used.

Returning to FIG. 7, in operation 706, tungsten is deposited via a high temperature CVD process. In this operation, a reducing agent and a tungsten-containing precursor are flowed into a deposition chamber to deposit a bulk fill layer in the feature. An inert carrier gas may be used to deliver one or more of the reactant streams, which may or may not be pre-mixed. Unlike PNL or ALD processes, this operation generally involves flowing the reactants continuously until the desired amount of material is deposited. In certain embodiments the CVD process may take place in multiple stages, with multiple periods of continuous and simultaneous flow of reactants separated by periods of one or more reactant flows diverted.

Various tungsten-containing gases including, but not limited to, WF₆, WCl₆, and W(CO)₆ may be used as the tungsten-containing precursor. In certain embodiments the tungsten-containing precursor is a halogen-containing compound, such as WF₆. In certain embodiments the reducing agent is hydrogen gas, though other reducing agents may be used, including silane (SiH₄), disilane (Si₂H₆), hydrazine (N₂H₄), diborane (B₂H₆), and germane (GeH₄).

In some embodiments CVD filling of the feature is performed with a low tungsten precursor partial pressure. In some embodiments the tungsten precursor is WF₆, as noted above. In some embodiments CVD filling of the feature is performed at an elevated temperature. Tungsten film stress can be decreased with tungsten deposition at a low tungsten precursor partial pressure and an elevated temperature.

According to various embodiments the partial pressure of tungsten precursor in a process chamber containing the substrate is about 0.01 to 1 Torr. In certain embodiments the partial pressure of tungsten precursor in a process chamber containing the substrate is less than about 0.20 Torr, less than about 0.15 Torr, less than about 0.1 Torr, or less than about 0.09 Torr. In certain embodiments the total pressure in the process chamber in a process chamber containing the substrate is about 20 to 500 Torr during the CVD process.

The stress in a tungsten film is dependent on the thickness of the tungsten film. In some embodiments the stress in a 2000 Angstrom thick tungsten film deposited according to the method 700 is less than about 1.5 gigapascals, and in some embodiments less than about 1.0 gigapascals. In some embodiments the stress in a tungsten film deposited according to the method 700 is about 0.3 to 0.9 gigapascals.

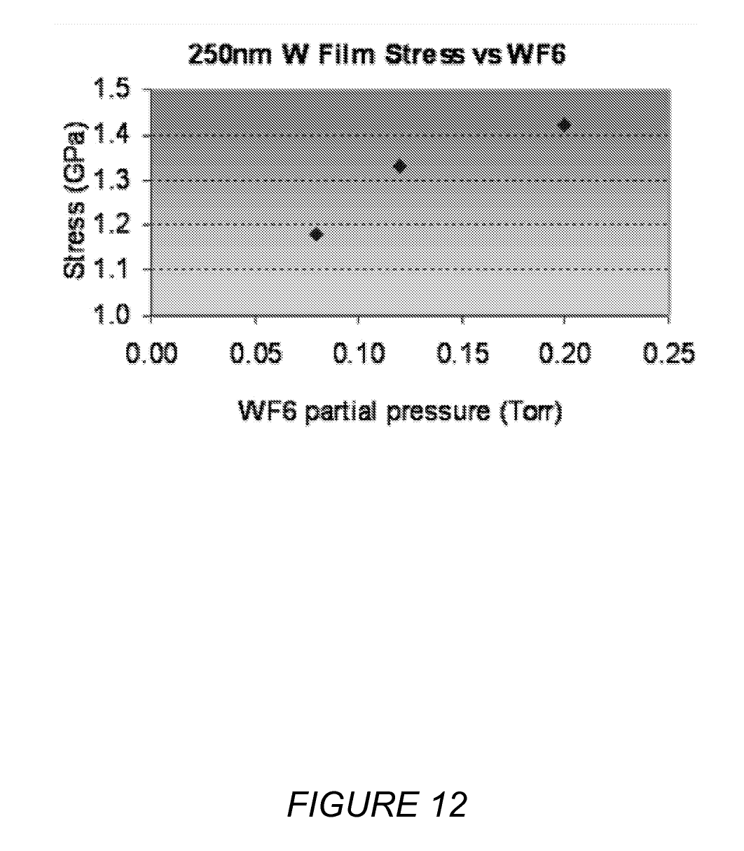

FIG. 12 is a plot illustrating film stress of a 250 nm thick tungsten film as a function of tungsten hexafluoride partial pressure during a tungsten CVD process, showing that tungsten film stress decreases with decreasing tungsten hexafluoride partial pressure.

According to various embodiments the temperature (process and/or substrate temperature) at which the CVD process is performed is in one of the following ranges: about 330 to 450° C., about 330 to 385° C., about 385 to 450° C., above about 330° C., or above about 385° C. In certain embodiments the process and/or substrate temperature is about 445° C.

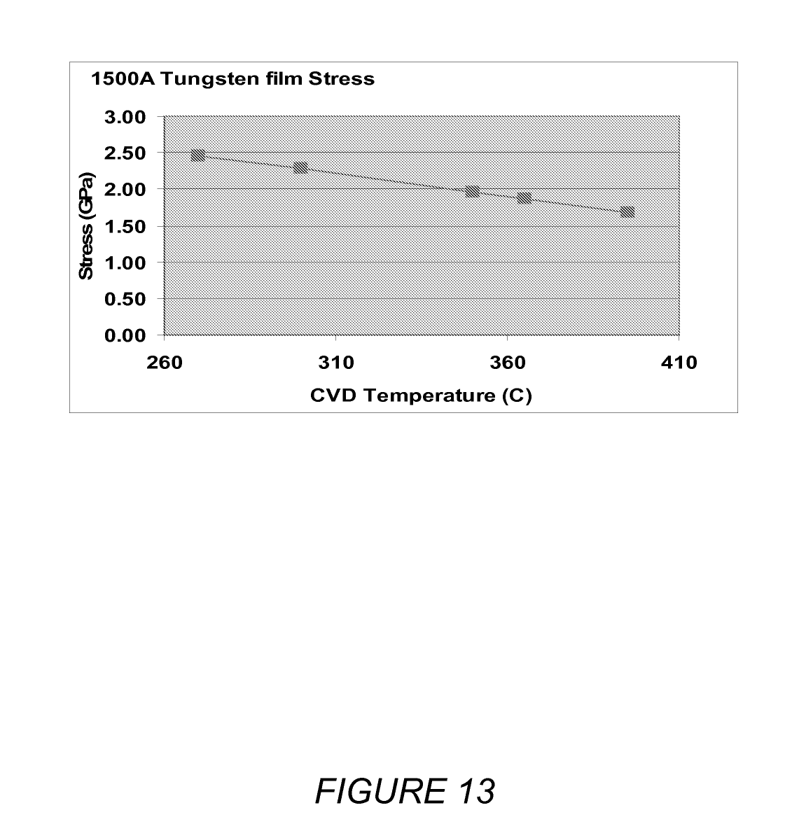

FIG. 13 is a plot illustrating film stress of a 1500 Angstrom thick tungsten film as a function of temperature during a tungsten CVD process, showing that tungsten film stress decreases with increasing temperature.

The residual stresses in thin films are conventionally divided into two categories: extrinsic stress and intrinsic stress. The most important extrinsic stress is due to thermal expansion between the film and the substrate. The intrinsic stress is associated with the film growth on the substrate.

The extrinsic stress in a film is in part caused by: 1) the difference in the thermal expansion coefficient of the material of the film and the thermal expansion coefficient of the material of the substrate onto which the film is deposited; and 2) the difference in the temperature at which deposition is performed and the temperature at which the stress measurement is performed. For example, a tungsten film may be deposited onto a silicon substrate, and tungsten has a different thermal expansion coefficient than silicon. If the deposition is performed at a high temperature and the stress measurement is performed at a low temperature, e.g., room temperature, one of ordinary skill in the art would expect a large film stress due to the temperature difference. If the deposition is performed at room temperature and the stress measurement is performed at room temperature, it would be expected that little or no film stress would result. The stress due to thermal expansion coefficient differences for a thin tungsten film on a silicon substrate is about 0.7×ΔT×10⁷ dyne/cm² (gigapascals). The trend shown in FIG. 13, with tungsten film stress decreasing with increasing temperature, is unexpected. Without being bound by any particular theory, it is believed that this is due to differences in tungsten film properties when tungsten is deposited at different temperatures and/or growth stresses not relaxing at low deposition temperatures.

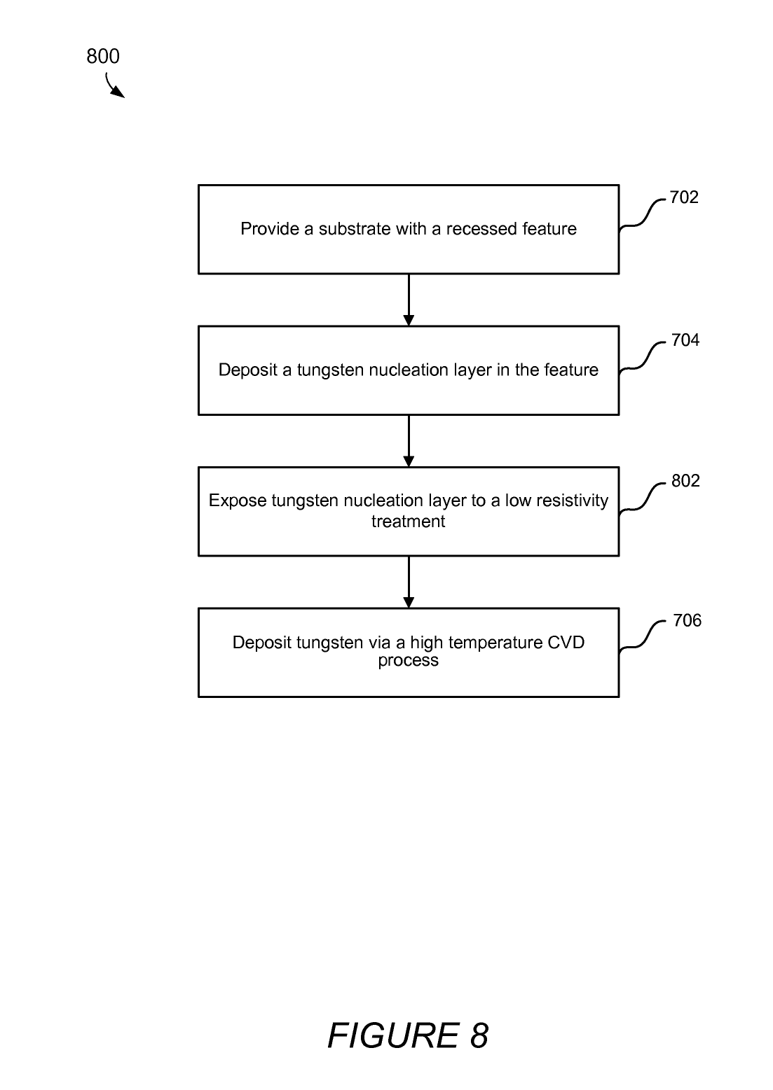

FIG. 8 depicts a process flow diagram illustrating operations in a method 800 of depositing low stress tungsten according to certain embodiments. Embodiments of the method 800 may be similar to the method 700 in FIG. 7, with the addition of process operation 802.

In operation 702, a substrate having a recessed feature is provided, as described above.

In operation 704, a tungsten nucleation layer is deposited in the feature, as described above.

In operation 802, the tungsten nucleation layer is exposed to a low resistivity treatment. In some embodiments the low resistivity treatment includes a plurality of reducing agent pulses. The plurality of reducing agent pulses improves the resistivity of the deposited tungsten film. Such treatment operations are described further below and in more detail in U.S. Pat. No. 7,772,114 and U.S. Patent Publication No. 2010/015969, both of which are incorporated by reference herein.

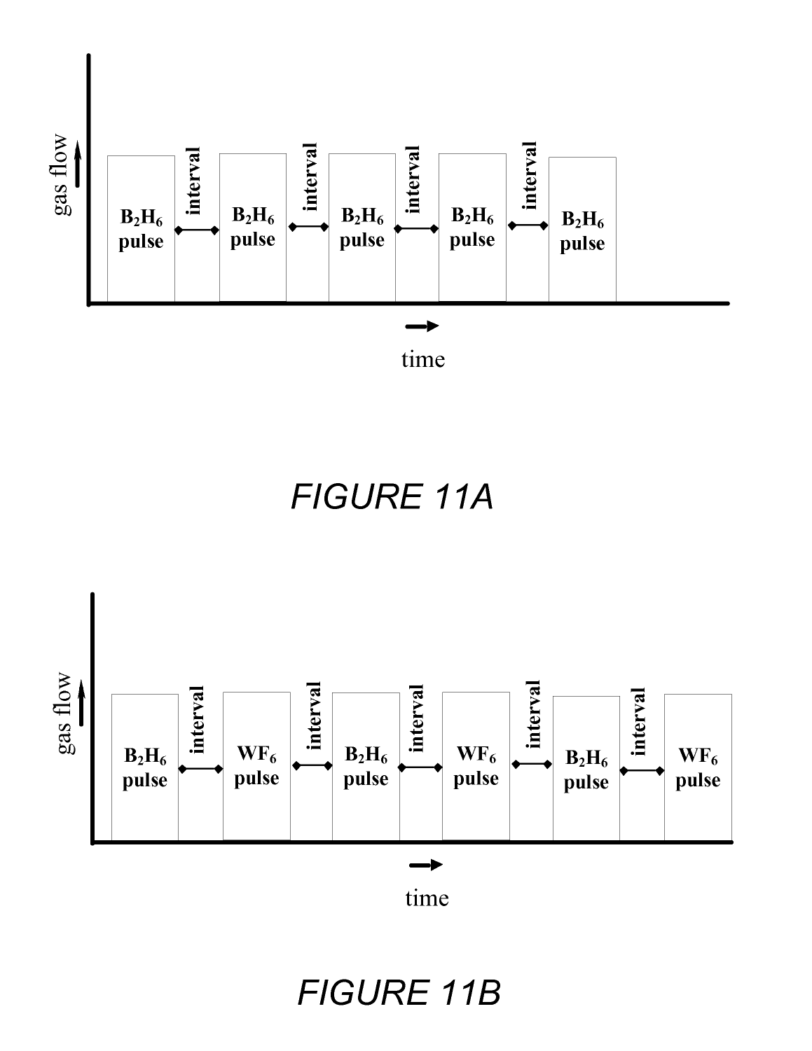

FIGS. 11A and 11B illustrate examples of gas pulse sequences of low resistivity treatments according to certain embodiments. FIG. 11A shows an example of a pulse sequence as described in U.S. Pat. No. 7,772,114, incorporated by reference herein. The treatment process described therein involves exposing the deposited nucleation layer to multiple pulses of a reducing agent without intervening pulses of another reactive compound. In FIG. 11A, diborane is depicted as the reducing agent, though other reducing agents may be used. The treatment lowers resistivity, while providing good adhesion and resistance non-uniformity. Notably, using multiple reducing agent pulses is shown to provide significantly improved resistivity and uniformity compared to using a single reducing agent pulse, even with the same overall exposure time. Too many reducing agent pulses, however, may lead to poor adhesion of the eventual tungsten film to the underlying layer. An optimal number of pulses, e.g., about 2 to 8, are used to obtain low resistivity, low non-uniformity, and acceptable adhesion. Unlike some embodiments of the nucleation layer deposition process described in FIG. 10, the low resistivity treatment operation may be performed with hydrogen in the background. Thus, transitioning from the nucleation operation to the low resistivity treatment operation may involve turning on a flow of hydrogen in certain embodiments. Also, in certain embodiments a nucleation layer is deposited in a first station of a multi-station deposition chamber, with the low resistivity treatment performed in a second station. Transitioning from the nucleation deposition to the low resistivity treatment involves transferring the substrate to the second station.

FIG. 11B shows another example of a pulse sequence in which the nucleation layer is exposed to multiple cycles of alternating reducing agent and a tungsten-containing precursor pulses. Diborane (B₂H₆) and tungsten hexafluoride (WF₆) are shown as the reducing agent and tungsten-containing precursor, respectively, though certain embodiments may use other compounds. Alternating pulses of a reducing agent and tungsten-containing precursor are also used to deposit the tungsten nucleation layer, but in the treatment operation, typically substantially no tungsten is deposited. As used herein, substantially no tungsten refers to no more than about an atomic layer deposited during the entire treatment operation. The flow rate and/or pulse time of the tungsten-containing precursor is limited to only scavenge the excess boron on the surface and in the chamber from the low-resistivity treatment, reducing the boron impurity. This in turn results in less micro-peeling and better film adhesion in certain embodiments. Accordingly, tungsten-containing precursor pulse exposure time and/or flow rate (relative to the reducing agent pulse) during the treatment may be less than that used to deposit the nucleation layer.

Some combination of the pulse sequences shown in FIGS. 11A and 11B may also be performed in certain embodiments. In certain embodiments the multi-pulse treatment operation is performed at a temperature below about 350° C., for example about 250 to 350° C. or about 250 to 325° C. In certain embodiments the temperature is around 300° C. According to various embodiments the total amount of diborane (or other boron-containing reducing agent) exposure may be from about 1×10⁻⁵ to 1×10⁻² moles, or more particularly, from about 1×10⁻⁴ to 1×10⁻³ moles during the multi-pulse treatment.

In some embodiments a low resistivity treatment differs from a PNL nucleation layer deposition method in that the WF₆ flow rate is decreased and the B₂H₆ flow rate is increased or remains the same in the low resistivity treatment. Further, in some embodiments of a low resistivity treatment, hydrogen is used, and in some embodiments of a PNL nucleation layer deposition method, hydrogen is not used. For example, in a PNL nucleation layer deposition method, the WF₆ partial pressure may be greater than about 0.15 Torr and the B₂H₆ partial pressure may be greater than about 0.2 Torr, while in a low resistivity treatment, the WF₆ partial pressure may be less than about 0.05 Torr and the B₂H₆ partial pressure may be greater than about 0.2 Torr.

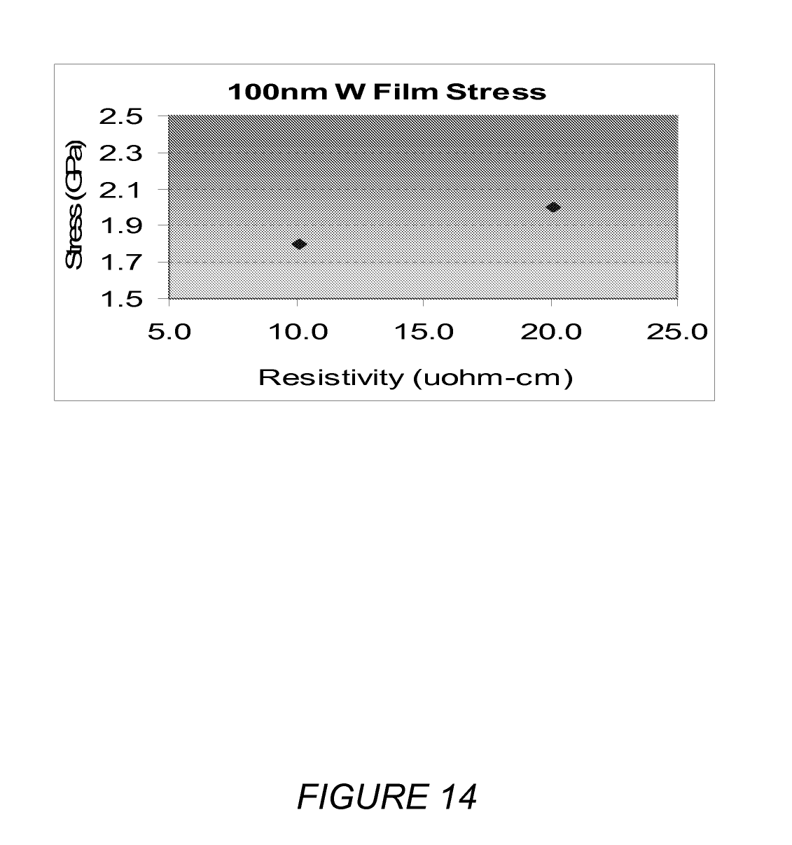

Film stress may be decreased with a low resistivity treatment of a tungsten nucleation layer. A low resistivity treatment of a tungsten nucleation layer results in large grains in tungsten deposited on such a treated nucleation layer. The tungsten deposited on the nucleation layer may also have reduced grain boundary energies. Large grains and low grain boundary energies correlate to a low film stress. FIG. 14 is a plot illustrating film stress of a 100 nm thick tungsten film as a function of film resistivity, showing that reducing the resistivity of a tungsten film reduces the film stress.

After the low resistivity treatment, in operation 706, tungsten is deposited via a high temperature CVD process, as described above.

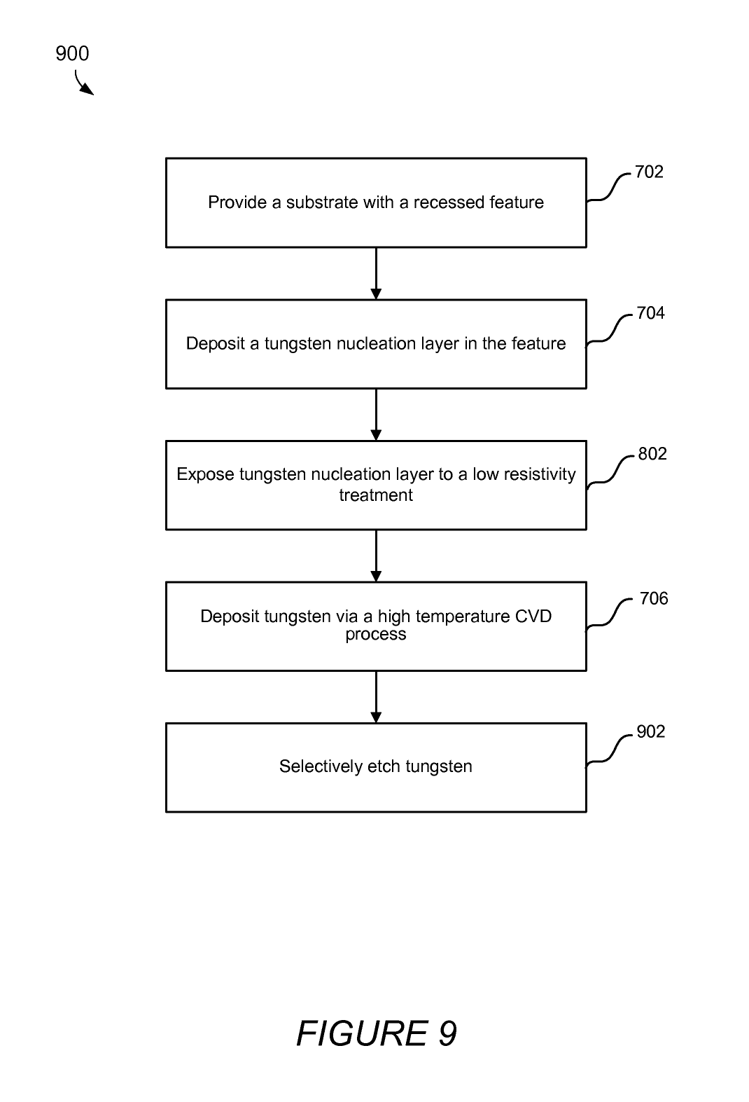

FIG. 9 depicts a process flow diagram illustrating operations in a method of depositing low stress tungsten 900 according to certain embodiments. Embodiments of the method 900 may be similar to the method 700 in FIG. 7 or the method 800 in FIG. 8, with the addition of process operation 902.

In operation 702, a substrate having a recessed feature is provided, as described above.

In operation 704, a tungsten nucleation layer is deposited in the feature, as described above.

In operation 802, the tungsten nucleation layer is exposed to a low resistivity treatment, as described above.

In operation 706, tungsten is deposited via a high temperature CVD process, as described above. In embodiments of the method 900, the feature is not entirely filled with tungsten in operation 706. For example, the feature opening may be partially filled or filled before the feature cavity is filled.

In operation 902, the tungsten is selectively etched. For example, if the feature opening is or will be filled before the feature cavity is filled, the tungsten may be selectively etched remove tungsten from the opening of the feature.

In some embodiments the tungsten etch process includes selectively removing a portion the deposited tungsten layer with an activated etching material at process conditions that substantially limit recombination of the activated etching material. Examples of etchant materials that can be used for selective removal of tungsten include nitrogen tri-fluoride (NF₃), tetra-fluoro-methane (CF₄), tetrafluoroethylene (C₂F₄), hexafluoroethane (C₂F₆), octafluoropropane (CF₈), tri-fluoro-methane (CHF₃), sulfur hexafluoride (SF₆), and molecular fluorine (F₂). In some embodiments an activated species, e.g., including radicals, ions, and/or high energy molecules, of the etchant material is produced. For example, an etchant material may be flowed through a remote plasma generator and/or subjected to an in-situ plasma.

After etching the tungsten, operation 706 may be performed again to fill the feature, in some embodiments. Further, in some embodiments, operations 706 and 902 may be repeatedly performed until the feature is filled with the desired amount of low stress tungsten. In certain embodiments, a final deposition operation 706 is performed to complete fill of the feature, without a further selective etch step after this final deposition operation.

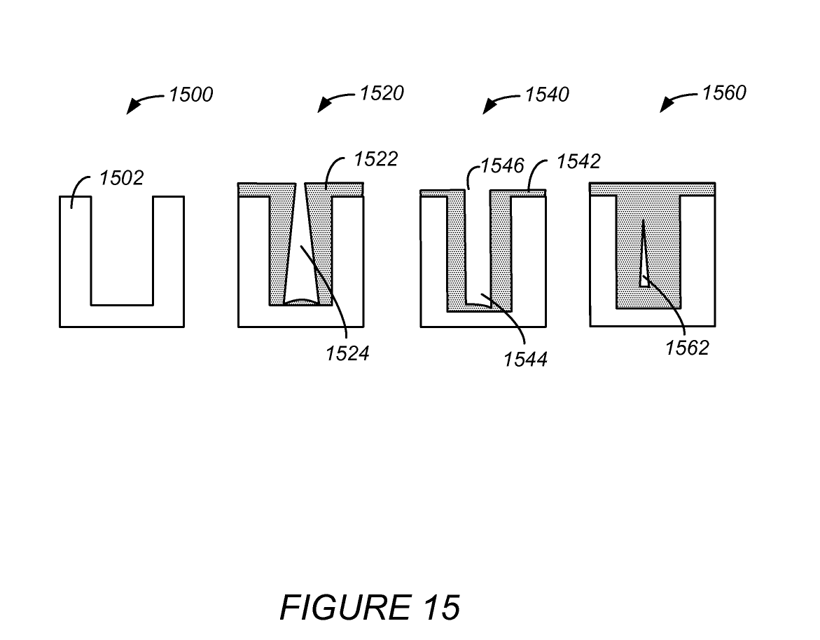

FIG. 15 is a schematic diagram illustrating feature cross-sections at different stages of a tungsten deposition process. Cross-section 1500 shows a substrate 1502 with a high-aspect ratio feature. Cross-section 1520 shows the high-aspect ratio feature partially filled with tungsten 1522. For example, the feature may be partially filled with tungsten after performing operations 704, 802, and 706. A large seam 1524 is present in the partially filled feature. Seams may be present in such high-aspect ratio features filled with tungsten due to the high temperature tungsten CVD process having poor step coverage when the feature has a high-aspect ratio. Cross-section 1540 shows the high-aspect ratio feature partially filled with tungsten after the tungsten etch process 902. The tungsten etch process selectively etches tungsten at the top field 1542 rather than at the bottom of the feature 1544, which increases the size of the opening 1546 of the feature. Cross-section 1560 shows the high-aspect ratio feature filled with tungsten. For example, the feature may be filled with tungsten with operation 706. In certain embodiments the tungsten deposited into the feature includes a seam 1562 that is open and is not filled with tungsten. In other embodiments, the feature may be substantially filled with tungsten with little or no seam.

Further descriptions of depositing tungsten and selectively etching tungsten to fill features including high-aspect ratio features are found in U.S. patent application Ser. Nos. 12/535,464 and 12/833,823 and both of which are herein incorporated by reference in their entireties.

Embodiments of the method 900 are also applicable to depositing tungsten in through silicon vias (TSVs). When depositing tungsten in TSVs, a thick tungsten overburden may cause wafer bowing and/or warping. Using operations described above, include the tungsten deposition operations, e.g., operation 706, and the tungsten etching operations, e.g., operation 902, a feature may be filled with minimal tungsten overburden. Further, a low stress tungsten film may not significantly contribute to wafer bowing and/or warping. A description of depositing tungsten in through silicon vias is found in U.S. patent application Ser. No. 12/534,566, which is herein incorporated by reference in its entirety.

Measurements of tungsten film stress of tungsten films deposited with the method 900 show that performing the tungsten etch process in operation 902 does not significantly increase or decrease the tungsten film stress.

In certain embodiments of the methods 700, 800, and 900 described above, transitioning from operations 702, 704, 802, 706, and 902 involve moving the substrate from one station to another in a multi-station chamber. In certain embodiments some of the operations may be performed in a single station in a multi-station chamber.

As shown in FIG. 13, tungsten film stress may be increased by lowering the CVD process temperature. The tungsten film stress can increase up to 50% by lowering CVD process temperature from about 395 to 275° C., for example. Higher film stresses are expected with even lower CVD process temperatures, for example, less than about 150° C.

Low temperature tungsten CVD processes yield an extremely low growth rate for tungsten, less than about 1 Angstrom per second at 250° C., for example. In some embodiments after a tungsten nucleation layer is deposited, a high stress tungsten film of a desired thickness is deposited. Then, a high temperature tungsten CVD process with a higher growth rate may be used to complete the tungsten deposition.

FIG. 16 depicts a process flow diagram illustrating operations in a method of depositing high stress tungsten according to certain embodiments. Embodiments of the method 1600 may be similar to the method 800 in FIG. 8, with the addition of process operation 1602.

In operation 702, a substrate having a recessed feature is provided, as described above.

In operation 704, a tungsten nucleation layer is deposited in the feature, typically to conformally coat the sidewalls and bottom of the feature, as described above.

In operation 802, the tungsten nucleation layer is exposed to a low resistivity treatment, as discussed above.

In operation 1602, tungsten is deposited via a low temperature CVD process. In this operation, a reducing agent and a tungsten-containing precursor may be introduced into a deposition chamber to partially fill the feature, for example. An inert carrier gas may be used to deliver one or more of the reactant streams, which may or may not be pre-mixed. In certain embodiments the CVD process may take place in multiple stages, with multiple periods of continuous and simultaneous flow of reactants separated by periods of one or more reactant flows diverted.

Various tungsten-containing gases including, but not limited to, WF₆, WCl₆, and W(CO)₆ may be used as the tungsten-containing precursor. In certain embodiments the tungsten-containing precursor is a halogen-containing compound, such as WF₆. In certain embodiments the reducing agent is hydrogen gas, though other reducing agents may be used, including silane (SiH₄), disilane (Si₂H₆), hydrazine (N₂H₄), diborane (B₂H₆), and germane (GeH₄).

According to various embodiments the temperature (process and/or substrate temperature) at which the CVD process is performed is in one of the following ranges: about 110 to 330° C., about 110 to 300° C., about 110 to 260° C., below about 260° C., below about 150° C., or above about 110° C. In certain embodiments the process and/or substrate temperature is about 230° C.

Again, as noted above, FIG. 13 is a plot illustrating film stress of a 1500 Angstrom thick tungsten film as a function of temperature during a tungsten CVD process, showing that tungsten film stress increases with decreasing temperature.

In operation 706, tungsten is deposited via a high temperature CVD process, as described above. With the faster tungsten deposition rate with a high temperature CVD process, this process may be used to completely fill the feature or to deposit tungsten overburden, for example.

According to various embodiments, the operation 706 in FIG. 16 is performed at a temperature of at least about 100° C. higher than that of operation 1602, and in certain embodiments at a temperature of at least 50° C. higher or at least about 100 to 150° C. higher.

The thickness of tungsten deposited by a low temperature CVD process and a high temperature CVD process is variable. For example, the thickness of tungsten deposited by a low temperature CVD process and a high temperature CVD process depends on the stress level in the tungsten film that is desired and the size of the feature being filled. For the 30 nanometer technology node, a 20 nm tungsten film may be deposited with a low temperature CVD process, for example. Portions of a feature that are not filled with the low temperature CVD process may be filled with a high temperature CVD process, for example. Tungsten overburden may also be deposited with a high temperature CVD process, for example. In certain embodiments, between about 50% and 90% of the total tungsten deposited by CVD to is deposited by the low temperature operation.

Including nitrogen as one of the gasses present during the CVD process unexpectedly increases the tungsten film stress and reflectivity compared to depositing tungsten via a CVD process in the absence of nitrogen. In some embodiments tungsten film stress is increased by performing the tungsten CVD deposition process in the presence of nitrogen. In some embodiments the low temperature CVD process in operation 1602 and the high temperature CVD process in operation 706 are performed in the presence of nitrogen. In some embodiments the low temperature CVD process in operation 1602 is performed in the presence of nitrogen. In some embodiments the high temperature CVD process in operation 706 is performed in the presence of nitrogen. In some embodiments the nitrogen partial pressure during the CVD process is about 0.1 to 10 Torr.

While not wanting to be bound by any theory, it is believed that the increase in tungsten film stress when tungsten is deposited via a CVD process in the presence of nitrogen may due to different growth mechanisms of tungsten when nitrogen is present.

In some embodiments the stress in the tungsten film deposited according to the method 1600 is at least about 2.75 gigapascals. In some embodiments the stress in the tungsten film deposited according to the method 1600 with operation 1602 and/or operation 706 performed in the presence of nitrogen is at least about 3.0 gigapascals.

Table 1 shows the effects nitrogen on a tungsten CVD deposition process. Table 1 shows film stress and reflectivity data for tungsten deposited via a CVD process without and with nitrogen (N₂) present during the deposition process.

TABLE 1
Film stress and reflectivity for tungsten deposited
via a CVD process with and without nitrogen (N₂)
present during the deposition process.

| | XRF cap | | | |
|---|---|---|---|---|
| | thickness | Resistivity | Stress | Reflectivity to |
| Process | (Angstroms) | (μohm-cm) | (GPA) | Si |
| LRW MP + | 528 | 11.27 | 2.79 | 1.22 |
| CVD (no N2) | | | | |
| LRW MP with | 510 | 12.21 | 3.28 | 1.25 |
| 4000 (sccm) | | | | |
| N2 on CVD | | | | |
| % increase | | 8.4 | 17.6 | 2.5 |

In Table 1, LRW MP refers to 5 cycles (B₂H₆/WF₆) at 300° C. to deposit a nucleation layer of approximately 40 Angstroms followed by 5 cycles of (B₂H₆/WF₆) treatment at 395° C. with substantially no tungsten deposited during the multipulse treatment. CVD was performed by hydrogen reduction of WF₆ at 395° C.

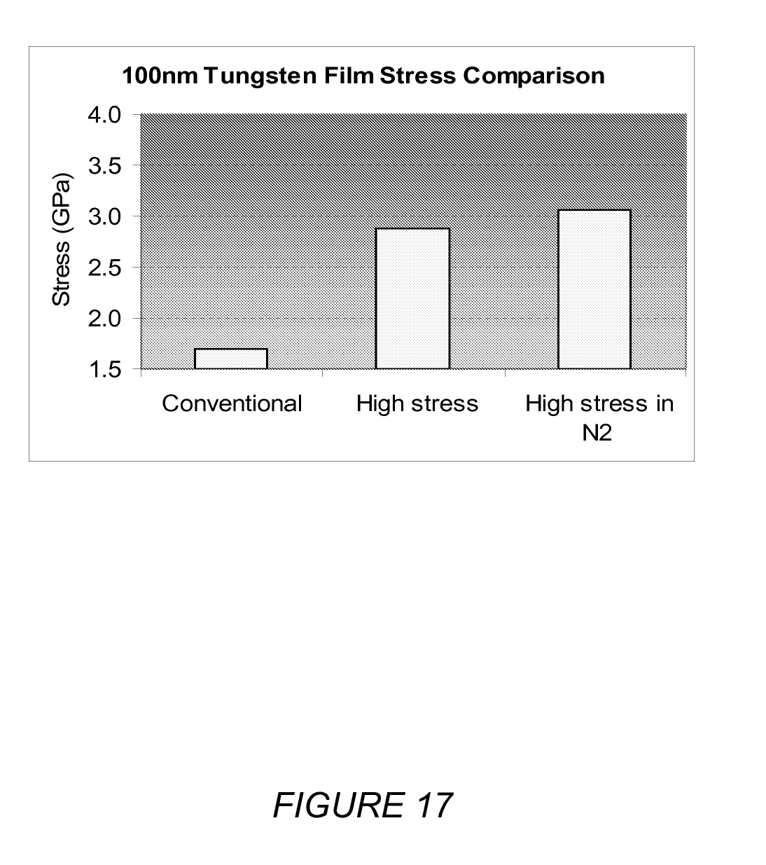

FIG. 17 is a bar graph illustrating the film stress of a 100 nm thick tungsten film for various tungsten deposition processes. The high stress tungsten CVD process produces a tungsten film having a significantly higher stress than a conventional CVD process. Further, a high stress tungsten CVD process performed in the presence of nitrogen produces a tungsten film having a stress that is a few tenths of a gigapascal higher than a high stress tungsten CVD process performed in the absence of nitrogen.

The presence of nitrogen during a tungsten CVD process may also reduce the surface roughness of the deposited tungsten, as further described in U.S. patent application Ser. Nos. 12/202,126 and 12/332,017, which are both herein incorporated by reference in their entireties.

In certain embodiments of the method 1600 described above, transitioning from operations 702, 704, 802, 1602, and 706 involve moving the substrate from one station to another in a multi-station chamber. In certain embodiments some of the operations may be performed in a single station in a multi-station chamber.

As noted above, the four MOSFET device embodiments, i.e., a PMOS device including high stress tungsten in the gate region, a NMOS device including high stress tungsten for contacts to the source and drain regions, a PMOS device including low stress tungsten for contacts to the source and drain regions, and a NMOS device including low stress tungsten in the gate region, may be implemented independently of each other. In some embodiments of a fabrication process of a semiconductor device including a PMOS device and a NMOS device, high stress tungsten may be deposited for a PMOS device gate and NMOS device contacts in a single set of process operations. A single set of process operations may make depositing high stress tungsten more cost effective, for example. In some embodiments of a fabrication process of a semiconductor device including a PMOS device and a NMOS device, low stress tungsten may be deposited for a NMOS device gate and PMOS device contacts in a single set of process operations. Similarly, a single set of process operations may make depositing low stress tungsten more cost effective, for example.

In some embodiments in order to deposit both high stress tungsten and low stress tungsten in a single semiconductor device, masks and/or sacrificial films are used to control regions on which the tungsten is deposited. Similarly, in certain embodiments in which both high stress tungsten and low stress tungsten are deposited in PMOS structures and NMOS structures being fabricated on a single semiconductor wafer, masks and/or sacrificial films are used to control regions on which the tungsten is deposited. Photolithography techniques employing masks and/or sacrificial films are well known to one of ordinary skill in the art.

Further, low stress and high stress tungsten films may be integrated in a metal gate deposition module, in a contact metallization deposition module, or in a “gate-last” integration scheme. Processing apparatus are further described, below. Because the integration of each of these modules may be independent of other modules, low stress or high stress tungsten films may be deposited in any type of tungsten deposition module.

Yet further, low stress tungsten films having different levels stress may be deposited in a NMOS device gate or a PMOS device contact. Similarly, high stress tungsten films having different levels stress may be deposited in a PMOS device gate or a NMOS device contact. The stress level of a tungsten film may be varied with deposition parameters in order to optimize device performance.

### Apparatus

The methods of the invention may be carried out in various types of deposition apparatus available from various vendors. Examples of suitable apparatus include a Novellus Concept-1 Altus™, a Concept 2 Altus™, a Concept-2 ALTUS-S™, Concept 3 Altus™ deposition system, an Altus Max™, or any of a variety of other commercially available CVD tools. In some cases, the process can be performed on multiple deposition stations sequentially. See, e.g., U.S. Pat. No. 6,143,082, which is incorporated herein by reference. In some embodiments a nucleation layer is deposited, e.g., by a pulsed nucleation process at a first station that is one of two, five, or even more deposition stations positioned within a single deposition chamber. Thus, the reducing gases and the tungsten-containing gases are alternately introduced to the surface of the semiconductor substrate, at the first station, using an individual gas supply system that creates a localized atmosphere at the substrate surface.

A second station may then be used to complete nucleation layer deposition or to perform a multi-pulse low resistivity treatment. In certain embodiments a single pulse low resistivity treatment may be performed.

One or more stations may then be used to perform CVD as described above. Two or more stations may be used to perform CVD in a parallel processing operation. Alternatively, a wafer may be indexed to have the CVD operations performed over two or more stations sequentially. For example, in processes involving both low temperature and high temperature CVD operations, a wafer or other substrate is indexed from one CVD station to another for each operation.

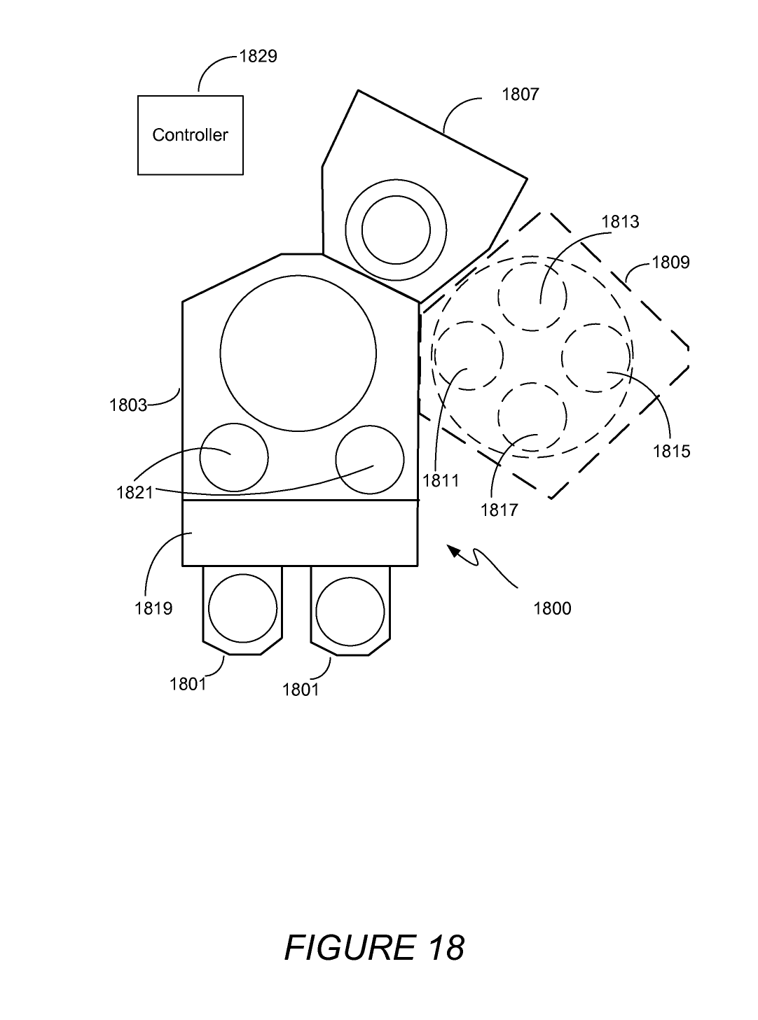

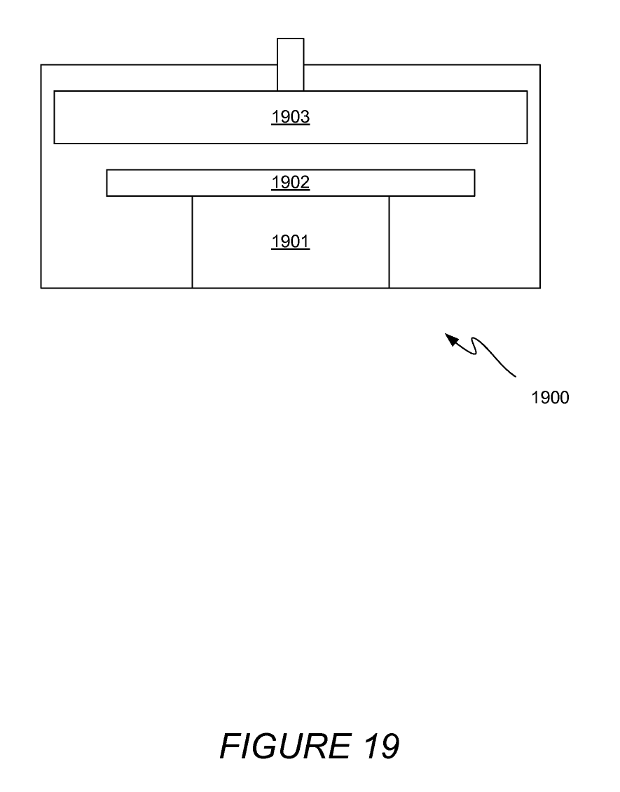

FIG. 18 is a schematic diagram of a processing system suitable for conducting tungsten deposition processes in accordance with various embodiments. The system 1800 includes a transfer module 1803. The transfer module 1803 provides a clean, pressurized environment to minimize the risk of contamination of substrates being processed as they are moved between the various reactor modules. Mounted on the transfer module 1803 is a multi-station reactor 1809 capable of performing PNL deposition, low resistivity treatments, and CVD according to various embodiments. Chamber 1809 may include multiple stations, including stations 1811, 1813, 1815, and 1817, which may sequentially perform these operations. For example, chamber 1809 could be configured such that station 1811 performs PNL deposition, station 1813 performs the low resistivity treatment, and stations 1815 and 1817 perform CVD. Each deposition station includes a heated wafer pedestal and a showerhead, dispersion plate, or other gas inlet. An example of a deposition station 1900 is depicted in FIG. 19, including a wafer support 1902 and a showerhead 1903. A heater may be provided in a pedestal portion 1901.

Also mounted on the transfer module 1803 may be one or more single or multi-station modules 1807 capable of performing plasma or chemical (non-plasma) pre-cleans. The module may also be used for various other treatments, e.g., post liner tungsten nitride treatments. The system 1800 also includes one or more (in this case two) wafer source modules 1801 where wafers are stored before and after processing. An atmospheric robot (not shown) in an atmospheric transfer chamber 1819 first removes wafers from the source modules 1801 to the loadlocks 1821. A wafer transfer device (generally a robot arm unit) in the transfer module 1803 moves the wafers from loadlocks 1821 to and among the modules mounted on the transfer module 1803.

In certain embodiments a system controller 1829 is employed to control process conditions during deposition. The controller will typically include one or more memory devices and one or more processors. The processor may include a central processing unit or a computer, analog and/or digital input/output connections, stepper motor controller boards, etc.

The controller may control all of the activities of the deposition apparatus. The system controller executes system control software including sets of instructions for controlling the timing, mixture of gases, chamber pressure, chamber temperature, wafer temperature, RF power levels, wafer chuck or pedestal position, and other parameters of a particular process. Other computer programs stored on memory devices associated with the controller may be employed in some embodiments.

Typically there is a user interface associated with the controller. The user interface may include a display screen, graphical software displays of the apparatus and/or process conditions, and user input devices such as pointing devices, keyboards, touch screens, microphones, etc.

Computer program code for controlling the deposition and other processes in a process sequence may be written in any conventional computer readable programming language: for example, assembly language, C, C++, Pascal, Fortran, or others. Compiled object code or script is executed by the processor to perform the tasks identified in the program.

The controller parameters relate to process conditions such as, for example, process gas composition and flow rates, temperature, pressure, plasma conditions such as RF power levels and the low frequency RF frequency, cooling gas pressure, and chamber wall temperature. These parameters are provided to the user in the form of a recipe, and may be entered utilizing the user interface.

Signals for monitoring the process may be provided by analog and/or digital input connections of the system controller. The signals for controlling the process are output on the analog and digital output connections of the deposition apparatus.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in pedestal or chuck. Appropriately programmed feedback and control algorithms may be used with data from these sensors to maintain desired process conditions. The foregoing describes implementation of embodiments of the invention in a single or multi-chamber semiconductor processing tool.

The apparatus/processes described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### Other Embodiments

While the invention has been described in terms of several embodiments, there are alterations, modifications, permutations, and substitute equivalents, which fall within the scope of this invention. For example, embodiments have been described for depositing low stress or high stress tungsten film in a feature. The methods described above may also be used to deposit low stress of high stress tungsten films on blanket surfaces. These may be formed by a blanket deposition of a tungsten layer (by a process as described above), followed by a patterning operation that defines the location of current carrying tungsten lines and removal of the tungsten from regions outside the tungsten lines. The methods described above are also applicable for forming other metallic films.

Embodiments of the methods may also be used for fabricating semiconductor structures with backside stress layers, as further described in U.S. Pat. No. 7,670,931, which is incorporated herein by reference in its entirety

It should also be noted that there are many alternative ways of implementing the methods and apparatuses of the present invention. It is therefore intended that the following appended claims be interpreted as including all such alterations, modifications, permutations, and substitute equivalents as fall within the true spirit and scope of the present invention.

What is claimed is:

1. A method comprising:
providing a substrate to a chamber, the substrate having a field region and a feature recessed from the field region, the feature including sidewalls and a bottom;
depositing a tungsten nucleation layer on the sidewalls and the bottom of the feature; and
filling the feature with tungsten via a first chemical vapor deposition process using a tungsten precursor, the substrate temperature being maintained at about 330 to 450° C. during the first chemical vapor deposition process, the partial pressure of the tungsten precursor in the chamber being less than about 1 Torr during the first chemical vapor deposition process.

2. The method recited in claim 1, wherein the partial pressure of the tungsten precursor in the chamber during the first chemical vapor deposition process is less than about 0.2 Torr.

3. The method recited in claim 1, further comprising:
after depositing the tungsten nucleation layer, exposing the tungsten nucleation layer to a plurality of reducing agent pulses without depositing more than about 1 Angstrom of tungsten.

4. The method recited in claim 3, wherein exposing the tungsten nucleation layer to a plurality of reducing agent pulses is performed without an intervening tungsten pulse operation between the pulses.

5. The method recited in claim 1, wherein depositing the tungsten nucleation layer includes exposing the substrate to a pulse of diborane and to a pulse of tungsten hexafluoride at low temperature.

6. The method recited in claim 1, wherein filling the feature with tungsten via a first chemical vapor deposition process includes introducing the tungsten precursor and a reducing agent into the chamber.

7. The method recited in claim 6, wherein the reducing agent includes hydrogen.

8. The method recited in claim 1, wherein the tungsten precursor includes tungsten hexafluoride.

9. The method recited in claim 1, further comprising:
before filling the feature with tungsten via a first chemical vapor deposition process, partially filling the feature with tungsten via a second chemical vapor deposition process, the substrate temperature being maintained at about 330 to 450° C. during the second chemical vapor deposition process, the partial pressure of the tungsten precursor in the chamber being less than about 1 Torr during the second chemical vapor deposition process; and
before filling the feature with tungsten via a first chemical vapor deposition process, etching a region of the formed tungsten.

10. The method recited in claim 1, wherein the substrate temperature is maintained at about 385 to 450° C. during the chemical vapor deposition process.

11. The method recited in claim 1, wherein an aspect ratio of the feature is at least 5:1.

12. The method recited in claim 1, wherein the substrate further includes a gate insulator disposed on the substrate, a metal disposed on the gate insulator, the metal forming the feature recessed from the field region.

13. The method recited in claim 1, further comprising:
before filling the feature with tungsten via a first chemical vapor deposition process, partially filling the feature with tungsten via a second chemical vapor deposition process, the substrate temperature being maintained at about 100 to 330° C. during the second chemical vapor deposition process, the second chemical vapor deposition process being performed at a temperature at least about 100° C. lower than the first chemical vapor deposition process.

14. The method recited in claim 1, further comprising: applying photoresist to the wafer substrate;
exposing the photoresist to light;
patterning the resist and transferring the pattern to the wafer substrate; and
selectively removing the photoresist from the wafer substrate.

15. A method comprising:
providing a substrate to a chamber, the substrate having a field region and a feature recessed from the field region, the feature including sidewalls and a bottom;
depositing a tungsten nucleation layer on the sidewalls and the bottom of the feature;
exposing the tungsten nucleation layer to a plurality of reducing agent pulses;
partially filling the feature with tungsten via a first chemical vapor deposition process, the substrate temperature being maintained at about 100 to 330° C. during the first chemical vapor deposition process; and
filling the feature with tungsten via a second chemical vapor deposition process, the substrate temperature being maintained at about 330 to 450° C. during the second chemical vapor deposition process, the second chemical vapor deposition process being performed at a temperature at least about 100° C. higher than the first chemical vapor deposition process.

16. The method recited in claim 15, wherein the first chemical vapor deposition process and the second chemical vapor deposition process are performed in a nitrogen atmosphere.

17. The method recited in claim 15, wherein a stress of the tungsten is at least about 2.75 gigapascals.

18. A PMOS transistor structure comprising:
a substrate;
a gate dielectric disposed on the substrate; and
a metal gate separated from the substrate by the gate dielectric;
the substrate including a source region and a drain region in the substrate on either side of the metal gate and a channel region underlying the gate dielectric, the channel region being strained by forces in the metal gate to decrease a lattice constant of the channel region.

19. A PMOS transistor structure comprising:
a substrate;
a gate dielectric disposed on the substrate; and
a metal gate separated from the substrate by the gate dielectric, wherein the substrate includes a source region and a drain region in the substrate on either side of the metal gate and a channel region underlying the gate dielectric;
the PMOS transistor structure further comprising:
a first metal contact contacting the source region, the source region being unstrained by the first metal contact; and
a second metal contact contacting the drain region, the drain region being unstrained by the second metal contact.

20. A NMOS transistor structure comprising:
a substrate;
a gate dielectric disposed on the substrate;
a metal gate separated from the substrate by the gate dielectric; and
a dielectric film;
the substrate including a source region and a drain region in the substrate on either side of the metal gate and a channel region underlying the gate dielectric, the channel region being strained by the dielectric film and unstrained by the metal gate to increase a lattice constant of the channel region.

21. A NMOS transistor structure comprising:
a substrate;
a gate dielectric disposed on the substrate; and
a metal gate separated from the substrate by the gate dielectric, wherein the substrate includes a source region and a drain region in the substrate on either side of the metal gate and a channel region underlying the gate dielectric;
the NMOS transistor structure further comprising:
a first metal contact contacting the source region, the source region being strained by forces in the first metal contact to increase a lattice constant of the channel region; and
a second metal contact contacting the drain region, the drain region being strained by forces in the second metal contact to increase the lattice constant of the channel region.

22. A deposition apparatus comprising:
a deposition chamber, the deposition chamber configured to:
deposit a tungsten nucleation layer on sidewalls and a bottom of a feature, the feature being recessed from a field region of a substrate having the field region; and
fill the feature with tungsten via a first chemical vapor deposition process using a tungsten precursor, the substrate temperature being maintained at about 330 to 450° C. during the first chemical vapor deposition process, the partial pressure of the tungsten precursor in the deposition chamber being less than about 1 Torr during the first chemical vapor deposition process.

23. A system comprising the deposition apparatus of claim 22 and a stepper.

24. The deposition apparatus of claim 22, further comprising:
a controller comprising program instructions for conducting a process comprising:
depositing a tungsten nucleation layer on the sidewalls and the bottom of the feature; and
filling the feature with tungsten via the first chemical vapor deposition process using the tungsten precursor, the substrate temperature being maintained at about 330 to 450° C. during the first chemical vapor deposition process, the partial pressure of the tungsten precursor in the deposition chamber being less than about 1 Torr during the first chemical vapor deposition process.

25. A non-transitory computer machine-readable medium comprising program instructions for control of a deposition apparatus, the instructions comprising code for:
providing a substrate to the deposition apparatus, the substrate having a field region and a feature recessed from the field region, the feature including sidewalls and a bottom;
depositing a tungsten nucleation layer on the sidewalls and the bottom of the feature; and
filling the feature with tungsten via a first chemical vapor deposition process using a tungsten precursor, the substrate temperature being maintained at about 330 to 450° C. during the first chemical vapor deposition process, the partial pressure of the tungsten precursor in the deposition apparatus being less than about 1 Torr during the first chemical vapor deposition process.
